(19) United States
(12) Patent Application Publication
(10) Pub. No.: US 2026/0144054 A1
(43) Pub. Date: May 21, 2026

(54) SEMICONDUCTOR DEVICES AND METHODS OF FORMATION

(71) Applicant: Taiwan Semiconductor Manufacturing Company, Ltd., Hsinchu (TW)

(72) Inventors: Shih-En LAI, Taichung City (TW); Chan-yu HUNG, Tainan City (TW); Fei-Yun CHEN, Hinchu (TW)

(21) Appl. No.: 18/955,078

(22) Filed: Nov. 21, 2024

(51) Int. Cl. H01L 23/522; H01L 21/768; H01L 23/00; H01L 23/48; H01L 25/00; H01L 25/065

(52) U.S. Cl. CPC H10W 20/496; H10W 20/023; H10W 20/20; H10W 90/00; H10W 80/312; H10W 80/327; H10W 90/297; H10W 90/792

(57) ABSTRACT

A semiconductor die in a semiconductor package includes a through-substrate capacitor structure that extends through the device layer of the semiconductor die. The through-substrate capacitor structure may be electrically connected to a first interconnect layer on a first side of the semiconductor die, and to a second interconnect layer on a second side of the semiconductor die opposing the first side. Forming the through-substrate capacitor structure through the device layer of the semiconductor die enables the through-substrate capacitor structure to be formed to have a high aspect ratio, which provides for greater surface area for a bottom electrode and a top electrode of the through-substrate capacitor structure. The greater surface area enables a higher capacitance to be achieved for the through-substrate capacitor structure.

### BACKGROUND

Various semiconductor device packing techniques may be used to incorporate one or more semiconductor dies into a semiconductor die package. In some cases, semiconductor dies may be horizontally interconnected through an interposer. Additionally and/or alternatively, semiconductor dies may be arranged vertically in a semiconductor die package to achieve a smaller horizontal or lateral footprint of the semiconductor die package and/or to increase the density of the semiconductor die package. The semiconductor dies may be connected directly through die-to-die (or wafer-to-wafer) bonding and/or through interconnects and one or more interposers.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIG. 1 is a diagram of an example semiconductor package described herein.

FIG. 2 is a diagram of an example implementation of a through-substrate capacitor structure in the semiconductor die described herein.

FIGS. 3A-3H are diagrams of an example implementation of forming a semiconductor die described herein.

FIGS. 4A-4D are diagrams of an example implementation of forming a semiconductor package described herein.

FIG. 5 is a diagram of an example semiconductor package described herein.

FIG. 6 is a diagram of an example implementation of a through-substrate capacitor structure in the semiconductor die described herein.

FIGS. 7A-7D are diagrams of an example implementation of forming a semiconductor die described herein.

FIGS. 8A-8G are diagrams of an example implementation of forming a semiconductor package described herein.

FIGS. 9A-9G are diagrams of examples of a semiconductor die described herein.

FIG. 10 is a diagram of an example semiconductor package described herein.

FIG. 11 is a flowchart of an example process associated with forming a semiconductor device described herein.

### DETAILED DESCRIPTION

The following disclosure provides many different embodiments, or examples, for implementing different features of the provided subject matter. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

In some cases, a semiconductor die in a semiconductor package may be connected to interconnect layers on both sides of the semiconductor die. For example, a first interconnect layer may be included on a first side (e.g., a front side) of the semiconductor die, and a second interconnect layer may be included on a second side (e.g., a back side) of the semiconductor die opposing the first side. In some cases, the first interconnect layer may be used for routing signals throughout the semiconductor die, and the second interconnect layer may be used for providing power to the integrated circuit devices of the semiconductor die. Additionally and/or alternatively, one of the first or second interconnect layers may be bonded to another semiconductor die and may be used for inter-die communication, and the other interconnect layer may be connected to the connector of the semiconductor package for making external connections.

To enable signals and/or power to be routed between the first and second interconnect layers, one or more elongated conductive structures may be included through a device layer (e.g., a semiconductor layer or semiconductor substrate) in which the integrated circuit devices are included. The elongated conductive structure(s) (sometimes referred to as through-silicon vias or through-substrate vias (TSVs)) connect with one or more metallization layers in the first and second interconnect layers, and may be formed of electrically conductive metals such as copper (Cu) to achieve a low electrical resistance between the metallization layers in the first and second interconnect layers through the elongated conductive structure(s).

In some implementations described herein, a semiconductor die in a semiconductor package includes a through-substrate capacitor structure (e.g., a TSV capacitor structure) that extends through the device layer of the semiconductor die. The through-substrate capacitor structure may be electrically connected to a first interconnect layer on a first side (e.g., a front side) of the semiconductor die, and to a second interconnect layer on a second side (e.g., a back side) of the semiconductor die opposing the first side. The through-substrate capacitor structure may also extend into a portion of the first interconnect layer and/or into the second interconnect layer. The through-substrate capacitor structure may include a metal-insulator-metal (MIM) stack that includes a bottom electrode layer, an insulator layer, and a top electrode layer that extend through the device layer.

Forming the through-substrate capacitor structure through the device layer of the semiconductor die enables the through-substrate capacitor structure to be formed to have a high aspect ratio (e.g., a ratio of a height or depth of the through-substrate capacitor structure to a width of the through-substrate capacitor structure), which provides for greater surface area for the bottom electrode layer and the top electrode layer. The greater surface area enables a higher capacitance to be achieved for the through-substrate capacitor structure. The sidewalls of the through-substrate capacitor structure may be longer than a capacitor structure contained within one of the interconnect layers, and therefore a high capacitance can be achieved for the through-substrate capacitor structure without using complex masks for forming multiple trenches for the through-substrate capacitor structure. This also enables high capacitance can be achieved for the through-substrate capacitor structure without expanding the lateral footprint of the through-substrate capacitor structure.

Moreover, the first interconnect layer and the second interconnect layer may be electrically connected through the through-substrate capacitor structure. The through-substrate capacitor structure may be electrically connected to integrated circuit devices in the device layer of the semiconductor die through the first interconnect layer and/or the second interconnect layer. This enables the integrated circuits to be formed, such as DRAM cells, other types of memory cells, pixel sensor circuits that include capacitors, and other types of integrated circuits that include capacitors.

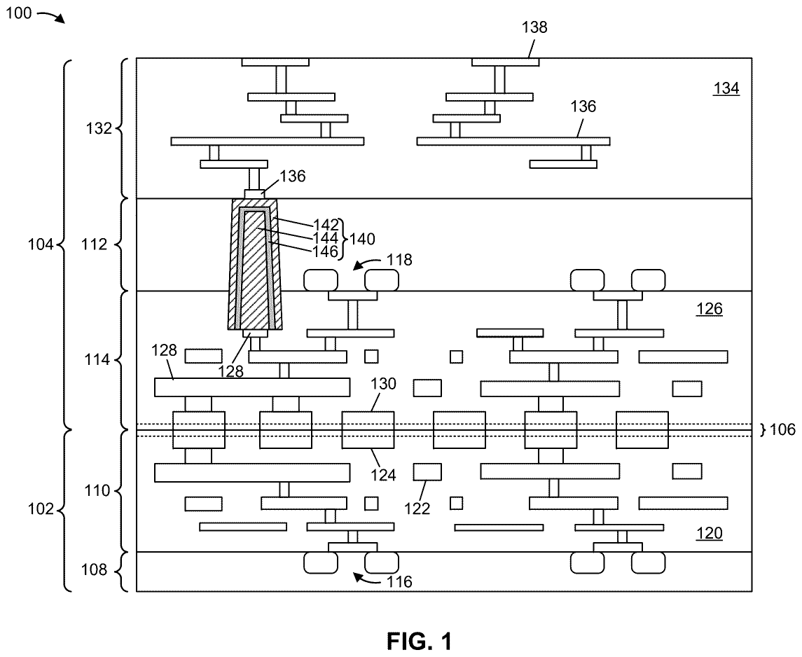

FIG. 1 is a diagram of an example semiconductor package 100 described herein. FIG. 1 illustrates a cross-section view of the semiconductor package 100. As shown in FIG. 1, the semiconductor package 100 includes a semiconductor die 102 and a semiconductor die 104 bonded at a bonding interface 106 such that the semiconductor dies 102 and 104 are stacked and vertically arranged in the semiconductor package 100. The bond between the semiconductor dies 102 and 104 may be formed by bonding semiconductor wafers together (e.g., wafer-to-wafer bonding), by bonding dies together (die-to-die bonding), and/or by bonding a die to a wafer (e.g., die-to-wafer bonding), among other example bonding configurations. A bonding tool may be used to perform a bonding operation to bond the semiconductor dies 102 and 104 by forming metal-to-metal bonds and/or dielectric-to-dielectric bonds at the bonding interface 106 between the semiconductor dies 102 and 104.

The semiconductor die 102 may include a system on chip (SoC) die, such as a logic die, a central processing unit (CPU) die, a graphics processing unit (GPU) die, a digital signal processing (DSP) die, an application specific integrated circuit (ASIC) die, and/or another type of SoC die. Additionally and/or alternatively, the semiconductor die 102 may include a memory die, an input/output (I/O) die, a pixel sensor die, and/or another type of semiconductor die. A memory die may include a static random access memory (SRAM) die, a dynamic random access memory (DRAM) die, a NAND die, a high bandwidth memory (HBM) die, and/or another type of memory die. The semiconductor die 104 may include the same type of semiconductor die as the semiconductor die 102, or may include a different type of semiconductor die.

As further shown in FIG. 1, the semiconductor die 102 may include a device layer 108 and an interconnect layer 110 above the device layer 108. The semiconductor die 104 may include a device layer 112 and an interconnect layer 114 below the device layer 112. The bonding interface 106 may be located between the interconnect layers 110 and 114, and may include portions of each of the interconnect layers 110 and 114. The bonding interface 106 may include conductive structures of the interconnect layers 110 and 114 that are bonded together by metal-to-metal bonds, and/or dielectric layers of the interconnect layers 110 and 114 that are bonded together by dielectric-to-dielectric bonds.

The device layer 108 may correspond to a portion of a semiconductor wafer on which the semiconductor die 102 was formed. Therefore, the device layer 108 may be referred to as the substrate layer of the semiconductor die 102. The device layer 112 may correspond to a portion of another semiconductor wafer on which the semiconductor die 104 was formed. Therefore, the device layer 112 may be referred to as the substrate layer of the semiconductor die 104. The device layers 108 and 112 may each include a silicon (Si) substrate, a substrate formed of a material including silicon, a III-V compound semiconductor material substrate such as gallium arsenide (GaAs), a silicon on insulator (SOI) substrate, or another type of semiconductor substrate.

The device layers 108 and 112 may respectively include integrated circuit devices 116 and 118 of the semiconductor dies 102 and 104. The integrated circuit devices 116 and 118 may each include transistors (e.g., planar transistors, fin field effect transistors (finFETs), gate all around (GAA) transistors), pixel sensors, capacitors, resistors, inductors, photodetectors, transceivers, transmitters, receives, optical circuits, and/or other types of passive and/or active integrated circuit devices.

The interconnect layers 110 and 114 may each include conductive structures that interconnect the integrated circuit devices 116 and 118 of the device layers 108 and 112, respectively. Additionally and/or alternatively, the interconnect layers 110 and 114 may each include conductive structures that electrically connect the semiconductor dies 102 and 104.

The interconnect layer 110 of the semiconductor die 102 includes one or more dielectric layers 120 that are arranged in a direction that is approximately perpendicular to the device layer 108. The dielectric layer(s) 120 may include backend dielectric layers (e.g., interlayer dielectric (ILD) layers, intermetal dielectric (IMD) layers) and etch stop layers (ESLs) that are arranged in an alternating manner in the interconnect layer 110. The dielectric layer(s) 120 may each include an oxide (e.g., a silicon oxide (SiOₓ) and/or another oxide material), an undoped silicate glass (USG), a boron-containing silicate glass (BSG), a fluorine-containing silicate glass (FSG), an extreme low dielectric constant (ELK) dielectric material having a dielectric constant that is less than approximately 2.5, a silicon nitride (SiₓN_{y}), silicon carbide (SiC), silicon oxynitride (SiON), and/or another suitable dielectric material.

The interconnect layer 110 includes a plurality of conductive structures 122 (e.g., electrically conductive structures) in the dielectric layer(s) 120. The conductive structures 122 are electrically coupled and/or physically coupled with one or more of the integrated circuit devices 116 in the device layer 108, and are electrically interconnected together in the interconnect layer 110. The conductive structures 122 correspond to circuit routing that enables signals and/or power to be provided to and/or from the integrated circuit devices 116. The conductive structures 122 may include a combination of conductive structures that extend primarily horizontally in the interconnect layer 110 (e.g., trenches, conductive lines) and that are interconnected by interconnect structures (e.g., vias) that extend primarily vertically in the interconnect layer 110. The conductive structures 122 may each include one or more electrically conductive materials such as tungsten (W), cobalt (Co), ruthenium (Ru), titanium (Ti), aluminum (Al), copper (Cu), gold (Au), and/or a combination thereof, among other examples of electrically conductive materials.

The conductive interconnects of the interconnect layer 110 may be arranged in a vertical manner to facilitate electrical signals and/or power to be routed between the device layer 108 and the semiconductor die 104, between integrated circuit devices 116 through the interconnect layer 110, and/or between the integrated circuit devices 116 and the integrated circuit devices 118 in the semiconductor die 104. The conductive structures 122 may be arranged in alternating layers of metallization layers (referred to as “M”-layers) and via layers (referred to as “V”-layers). Each metallization layer may include one or more conductive structures laterally arranged in the interconnect layer 110, and each via layer may include one or more interconnect structures that interconnect the metallization layers in the interconnect layer 110. As an example, a metal-0 (M0) layer may be located at the bottom of the interconnect layer 110 and may be coupled with the integrated circuit devices 116 in the device layer 108, a via-0 (V0) layer may be located above and coupled with the M0 layer in the interconnect layer 110, a metal-1 (M1) layer may be located above and coupled with the VO layer in the interconnect layer 110, a via-1 (V1) layer may be located above and coupled with the M1 layer in the interconnect layer 110, a metal-2 (M2) layer may be located above and electrically coupled with the V1 layer in the interconnect layer 110, and so on. In some implementations, the interconnect layer 110 includes nine (9) stacked metallization layers (e.g., M0-M8). In other implementations, the contact layer (referred to as “CO”-layer) may be located at the bottom of the interconnect layer 110 and may be coupled with the integrated circuit devices 116 in the device layer 108, a metal-1 (M1) layer may be located above and coupled with the CO layer in the interconnect layer 110, and so on. In some implementations, the interconnect layer 110 includes another quantity of stacked metallization layers.

At the bonding interface 106, the interconnect layer 110 may include a plurality of bonding pads 124. The bonding pads 124 may be electrically coupled with the conductive structures 122 in the interconnect layer 110 by bonding vias and/or other types of conductive structures. The bonding pads 124 may each include tungsten (W), cobalt (Co), ruthenium (Ru), titanium (Ti), aluminum (Al), copper (Cu), gold (Au), and/or a combination thereof, among other examples of electrically conductive metals.

As further shown in FIG. 1, the interconnect layer 114 of the semiconductor die 104 may include a similar combination and/or arrangement of structures and/or layers as the interconnect layer 110 of the semiconductor die 102. For example, the semiconductor die 104 may include a combination of one or more dielectric layers 126 and conductive structures 128 in the dielectric layer(s) 126. Moreover, the interconnect layer 114 may include bonding pads 130 that are electrically coupled with one or more of the conductive structures 128 (e.g., by bonding vias and/or other types of conductive structures). These layers and/or structures may have a reversed vertical arrangement relative to the semiconductor die 102, which enables the semiconductor die 102 and the semiconductor die 104 to be bonded at the bonding interface 106 such that the interconnect layer 110 and the interconnect layer 114 are facing each other.

At the bonding interface 106, the bonding pads 124 of the semiconductor die 102 and the bonding pads 130 of the semiconductor die 104 are directly bonded by metal-to-metal bonds. Moreover, a dielectric layer of the one or more dielectric layers 120 of the semiconductor die 102 and a dielectric layer of the one or more dielectric layers 126 of the semiconductor die 104 are directly bonded by dielectric-to-dielectric bonds.

As further shown in FIG. 1, the semiconductor die 104 may include another interconnect layer 132. The interconnect layer 114 may be located on a first side (e.g., a front side) of the device layer 112 of the semiconductor die 104, and the interconnect layer 132 may be located on a second side (e.g., a back side) of the device layer 112 opposing the first side. The interconnect layer 114 may be configured to route signals and/or power between the semiconductor dies 102 and 104, and/or may be configured to route signals and/or power between integrated circuit devices 118 of the semiconductor die 104. The interconnect layer 132 may be configured to route signals and/or power between the semiconductor die 104 and devices external to the semiconductor package 100. For example, the interconnect layer 132 may be configured to route signals and/or power between the semiconductor die 104 and an external high bandwidth memory (HBM) die, an external system on chip (SoC) die, an external input/output (I/O) die, and/or another type of device external to the semiconductor package 100.

The interconnect layer 132 of the semiconductor die 104 includes one or more dielectric layers 134 (e.g., ILD layers, IMD layers, ESLs) and conductive structures 136 (e.g., trenches, metallization layers, vias, interconnect structures) in the dielectric layer(s) 134. The dielectric layer(s) 134 may each include an oxide (e.g., a silicon oxide (SiOₓ) and/or another oxide material), a USG, a BSG, an FSG, an ELK dielectric material, a silicon nitride (SiₓN_{y}), silicon carbide (SiC), silicon oxynitride (SiON), and/or another suitable dielectric material. The conductive structures 136 may each include one or more electrically conductive materials such as tungsten (W), cobalt (Co), ruthenium (Ru), titanium (Ti), aluminum (Al), copper (Cu), gold (Au), and/or a combination thereof, among other examples of electrically conductive materials.

The interconnect layer 132 further includes connection structures 138 that enable the semiconductor package 100 to be attached to a substrate (e.g., an interposer, a printed circuit board (PCB)), another semiconductor die package, and/or to be attached to another structure.

The connection structures 138 may include bonding pads and/or another type of connection structures.

As further shown in FIG. 1, the semiconductor package 100 includes one or more through-substrate capacitor structures 140 that extend through the device layer 112 (e.g., the substrate layer) of the semiconductor die 104. A through-substrate capacitor structure 140 may extend into the interconnect layer 114 and may be physically coupled and/or electrically coupled with a conductive structure 128 (e.g., a metal pad) in the interconnect layer 114 at a first end, and that is physically coupled and/or electrically coupled with a conductive structure 136 (e.g., a metal pad) in the interconnect layer 132 at a second end vertically opposing the first end. A through-substrate capacitor structure 140 may be referred to as a TSV capacitor structure in that the through-substrate capacitor structure 140 extends fully through a semiconductor layer (e.g., a silicon substrate) of the device layer 112. The bottom of the through-substrate capacitor structure 140 (e.g., the second end) may be approximately co-planar with the bottom of the device layer 112.

As shown in FIG. 1, a through-substrate capacitor structure 140 may include a bottom electrode 142, a top electrode 144, and an insulator layer 146 between the bottom electrode 142 and the top electrode 144. The bottom electrode 142 may include a conformal electrode layer that conforms to sidewalls and a bottom surface of a recess in which the through-substrate capacitor structure 140 was formed. The insulator layer 146 may include a conformal dielectric layer that conforms to the profile of the bottom electrode 142. In some implementations, the top electrode 144 also includes a conformal electrode layer and conforms to the profile of the insulator layer 146. In these implementations, the remaining area in the recess may be filled in with additional bottom electrode layer/insulator layer/top electrode layer film stacks, and/or may be filled in with a dielectric plug. In some implementations, the top electrode 144 includes a top electrode plug that fills in the remaining area in the recess.

The top electrode 144 may be physically coupled and/or electrically coupled with a conductive structure 128 (e.g., a metal pad) in the interconnect layer 114 at the first end of the through-substrate capacitor structure 140. The bottom electrode 142 may be physically coupled and/or electrically coupled with a conductive structure 136 (e.g., a metal pad) in the interconnect layer 132 at the second end of the through-substrate capacitor structure 140.

The bottom electrode 142 and the top electrode 144 may each include one or more electrically conductive materials, such as copper (Cu), gold (Au), silver (Ag), nickel (Ni), tin (Sn), ruthenium (Ru), cobalt (Co), tungsten (W), titanium (Ti), one or more metals, one or more conductive ceramics, and/or another type of conductive material.

The insulator layer 146 may include one or more dielectric materials such as a silicon oxide material (SiOₓ such as SiO₂) and/or a silicon nitride material (SiₓN_{y} such Si₃N₄), among other examples. In some implementations, the insulator layer 146 includes a high dielectric constant (high-k) dielectric material having a dielectric constant of greater than approximately 3.9. Examples of such high-k dielectric materials include an aluminum oxide (AlₓO_{y} such as Al₂O₃), a tantalum oxide (TaₓO_{y} such as Ta₂O₅), a titanium oxide (TiOₓ such as TiO₂), a zirconium oxide (ZrOₓ such as ZrO₂), a hafnium oxide (HfOₓ such as HfO₂), a strontium titanium oxide (SrTiOₓ such as SrTiO₃), hafnium silicon oxide (HfSiOₓ such as HfSiO₄), lanthanum oxide (LaₓO_{y} such as La₂O₃), yttrium oxide (YₓO_{y} such as Y₂O₃), and/or amorphous lanthanum aluminum oxide (a-LaAlOₓ such as a-LaAlO₃), among other examples. In some implementations, the insulator layer 146 includes a multiple-layer thin film, where each layer includes a different high-k dielectric material. For example, the insulator layer 146 may include a dielectric film stack such as a zirconium oxide/aluminum oxide/zirconium oxide (ZrO₂/Al₂O₃/ZrO₂ or ZAZ).

As indicated above, FIG. 1 is provided as an example. Other examples may differ from what is described with regard to FIG. 1.

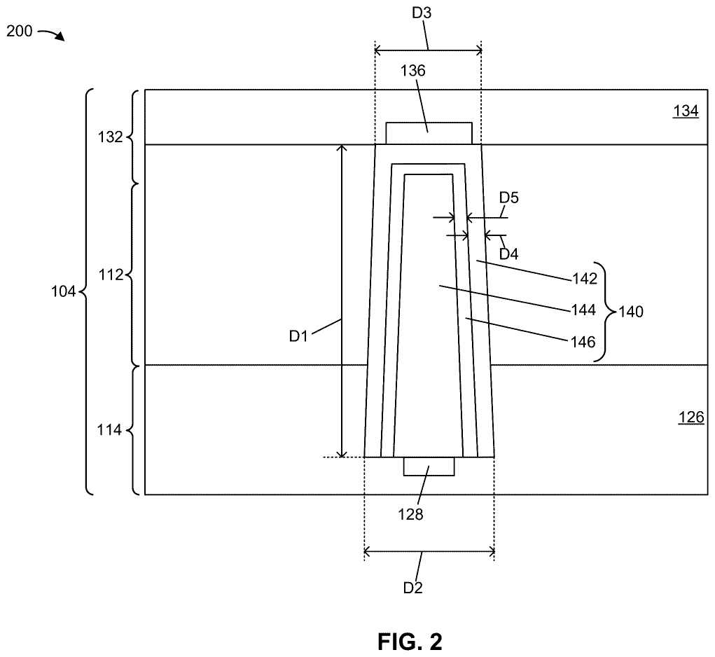

FIG. 2 is a diagram of an example implementation 200 of a through-substrate capacitor structure 140 in the semiconductor die 104 described herein. As shown in FIG. 2, the through-substrate capacitor structure 140 may have one or more example dimensions.

As shown in FIG. 2, an example dimension D1 corresponds to a vertical height of the through-substrate capacitor structure 140. In some implementations, the vertical height of the through-substrate capacitor structure 140 may be included in a range of approximately 10 microns to approximately 100 microns. However, other values for the range are within the scope of the present disclosure.

Another example dimension D2 corresponds to a top width (or top critical dimension (CD)) of the through-substrate capacitor structure 140, and another example dimension D3 corresponds to a bottom width (or bottom CD) of the through-substrate capacitor structure 140. The top width of the through-substrate capacitor structure 140 may be greater than the bottom width of the through-substrate capacitor structure 140 (e.g., D2>D3). The recess in which the through-substrate capacitor structure 140 is formed may be formed from the front side of the device layer 112. The top of the recess may have a greater width than the bottom of the recess because an etchant that was used to form the recess was in contact with the dielectric layer(s) 126 for a longer duration than the device layer 112, and therefore a greater amount of lateral etching may occur at the top of the recess in the dielectric layer(s) 126 than at the bottom of the recess in the device layer 112. Accordingly, the through-substrate capacitor structure 140 may have a similar cross-sectional profile where the top of the through-substrate capacitor structure 140 has a greater width (e.g., dimension D2) than the bottom of the through-substrate capacitor structure 140 (e.g., dimension D3).

In some implementations, the top width (e.g., the dimension D2) and the bottom width (e.g., the dimension D3) of the through-substrate capacitor structure 140 may each be included in a range of approximately 1 micron to approximately 10 microns. The top width may be closer to the top of the range than the bottom width, which may be closer to the bottom of the range than the top width. However, other values for the range are within the scope of the present disclosure.

The through-substrate capacitor structure 140 may have a high aspect ratio (e.g., a ratio of the height to the top width (e.g., D1:D2)). The high aspect ratio of the through-substrate capacitor structure 140 enables the height of the through-substrate capacitor structure 140 (e.g., the dimension D1) to be increased (which increases the capacitance of the through-substrate capacitor structure 140) while maintaining a relatively small lateral footprint (e.g., dimension D2) for the through-substrate capacitor structure 140 (which enables a high density of structures to be achieved in the semiconductor die 104). For example, the aspect ratio of the through-substrate capacitor structure 140 may be included in a range of approximately 5:1 to approximately 15:1. However, other values for the range are within the scope of the present disclosure.

As further shown in FIG. 2, another example dimension D4 of the through-substrate capacitor structure 140 corresponds to a thickness of the bottom electrode 142. In some implementations, the thickness of the bottom electrode 142 is included in a range of approximately 0.5 microns to approximately 5 microns. However, other values for the range are within the scope of the present disclosure.

As further shown in FIG. 2, another example dimension D5 of the through-substrate capacitor structure 140 corresponds to a thickness of the insulator layer 146. In some implementations, the thickness of the insulator layer 146 is included in a range of approximately 10 angstroms to approximately 1000 angstroms. However, other values for the range are within the scope of the present disclosure.

As indicated above, FIG. 2 is provided as an example. Other examples may differ from what is described with regard to FIG. 2.

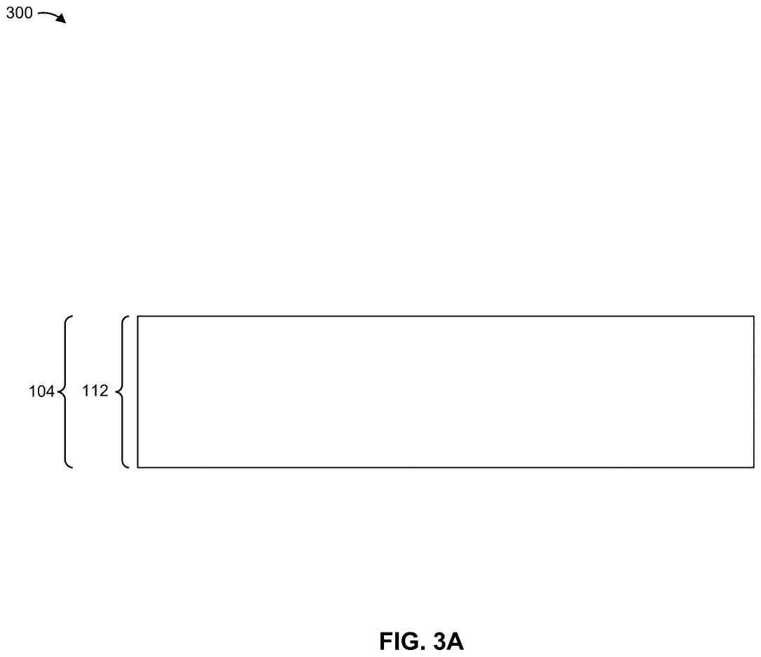

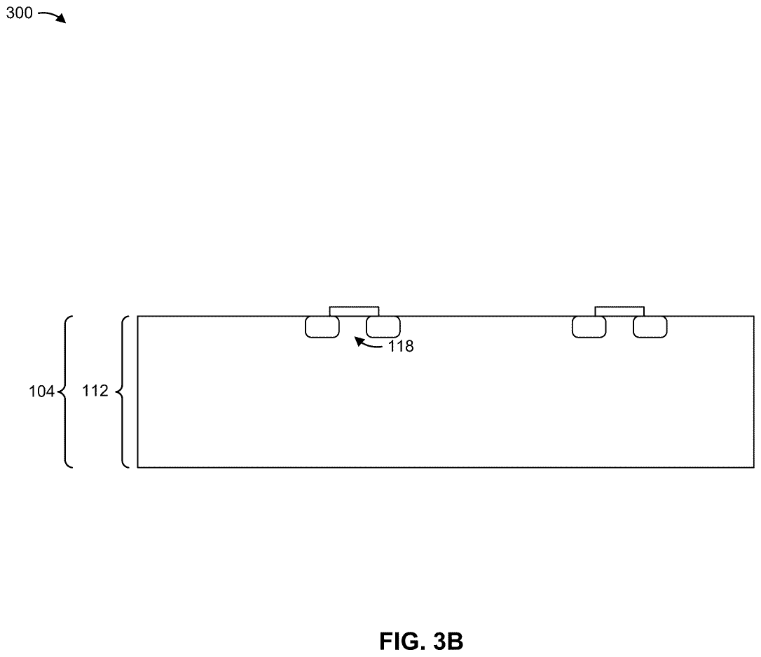

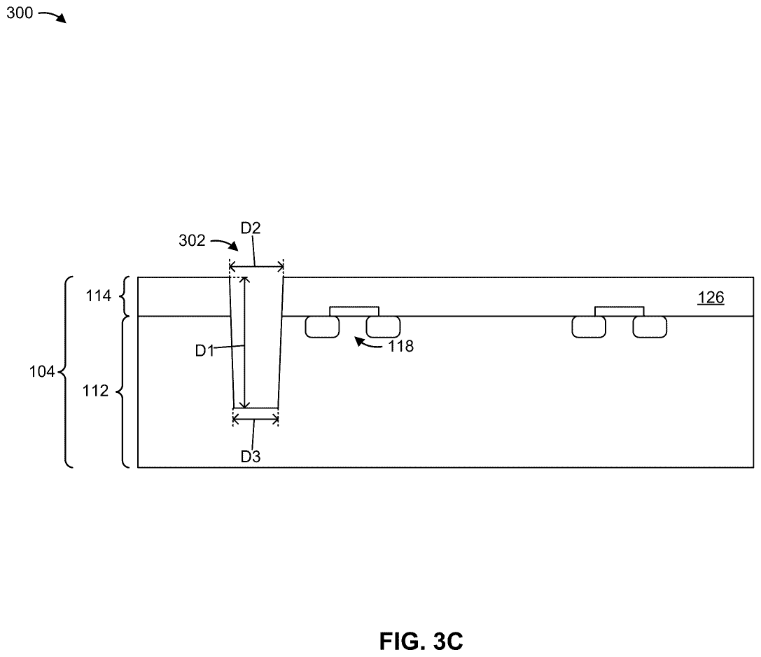

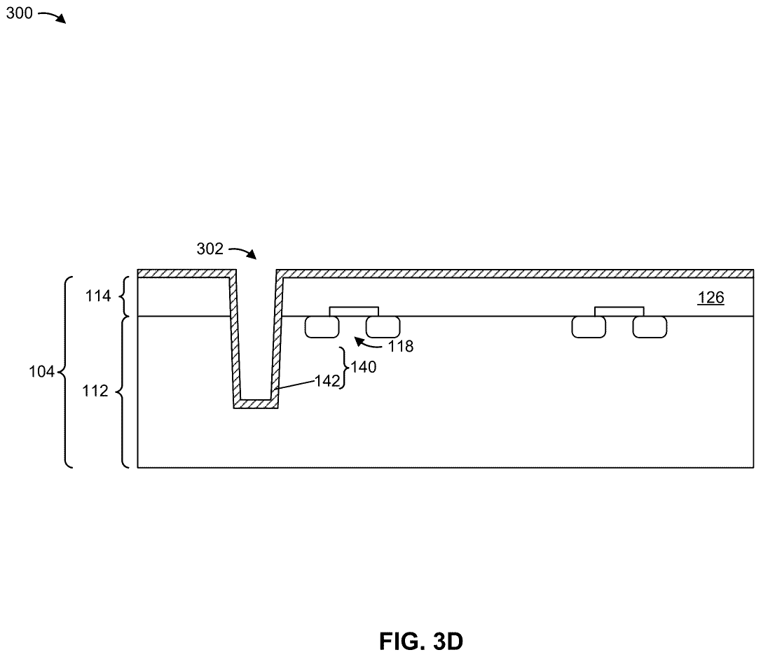

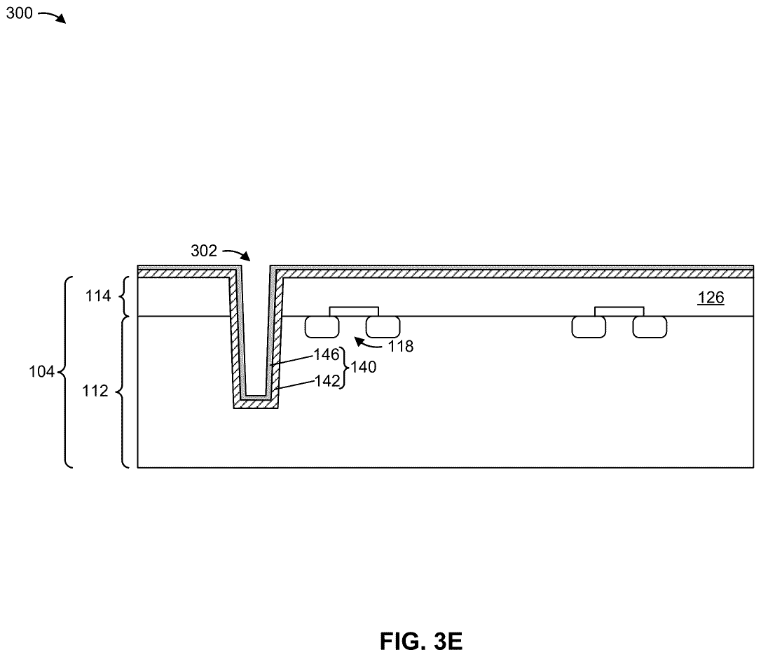

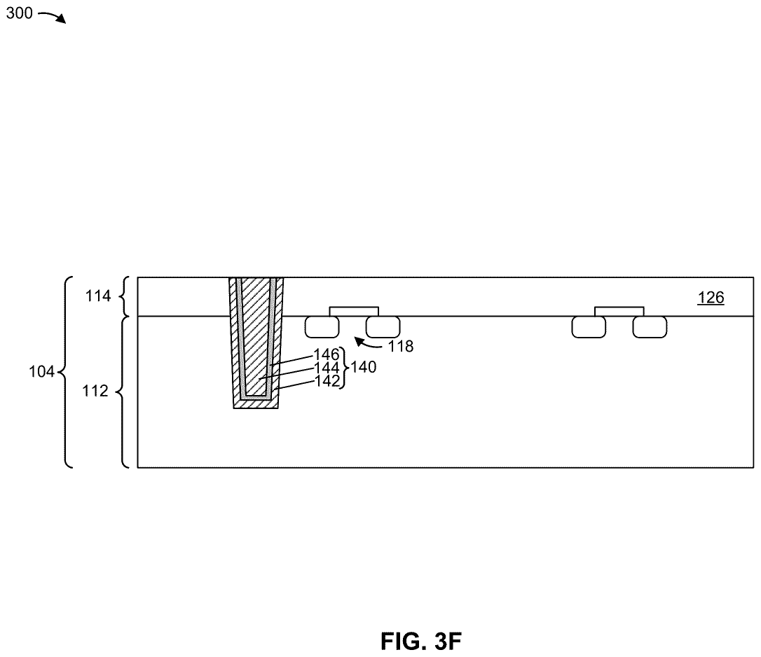

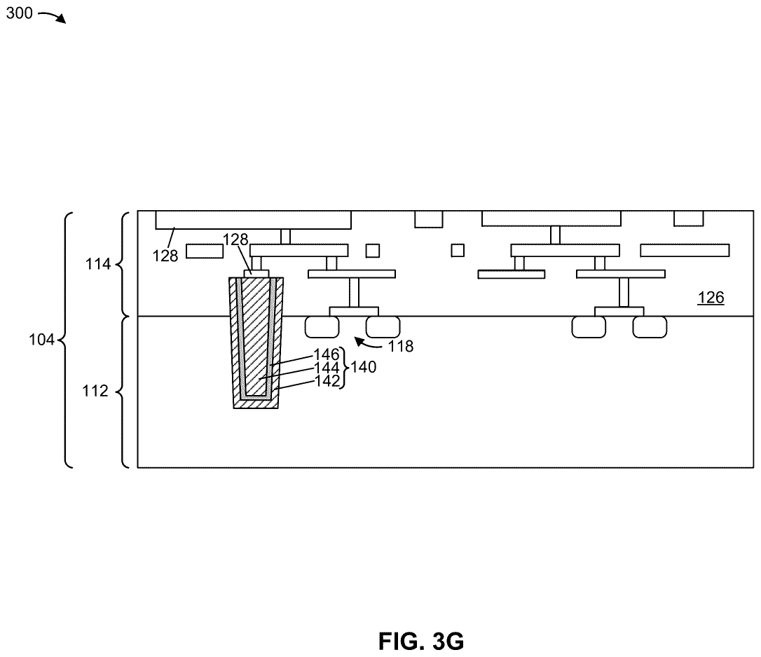

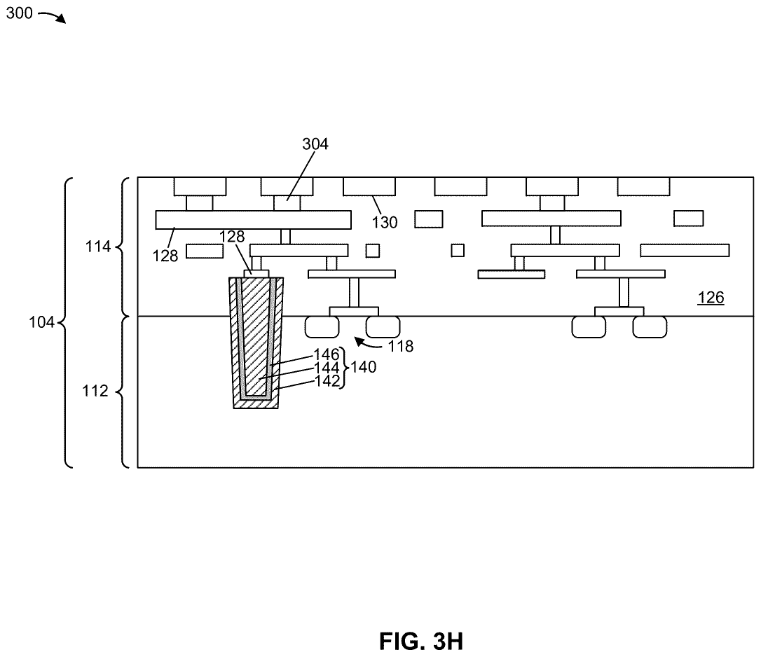

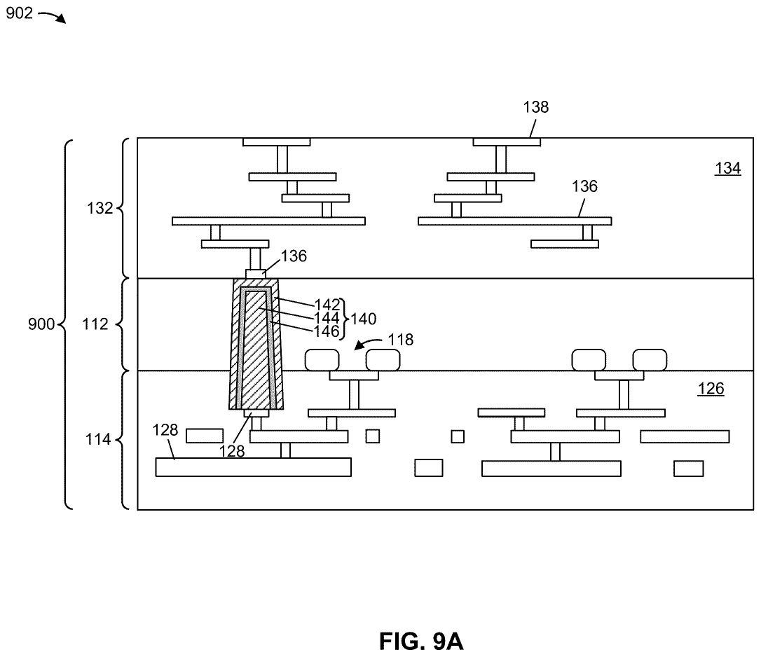

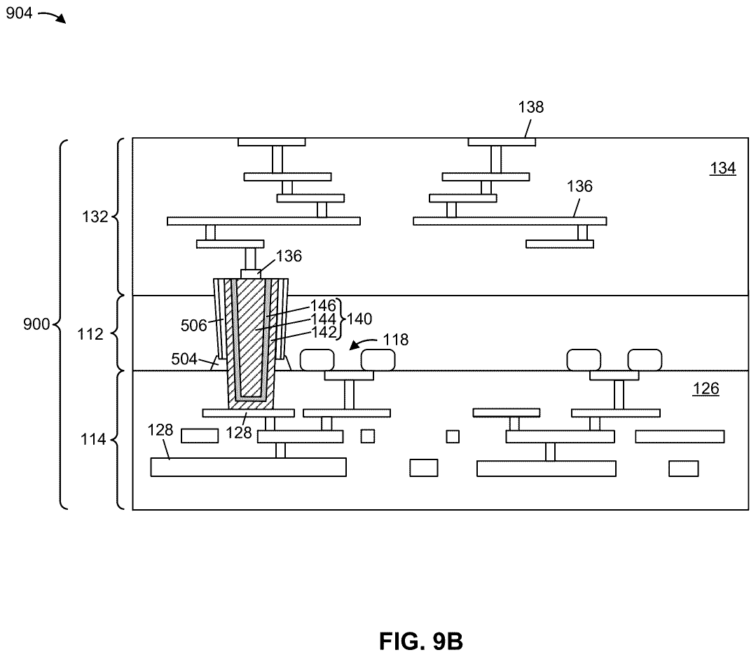

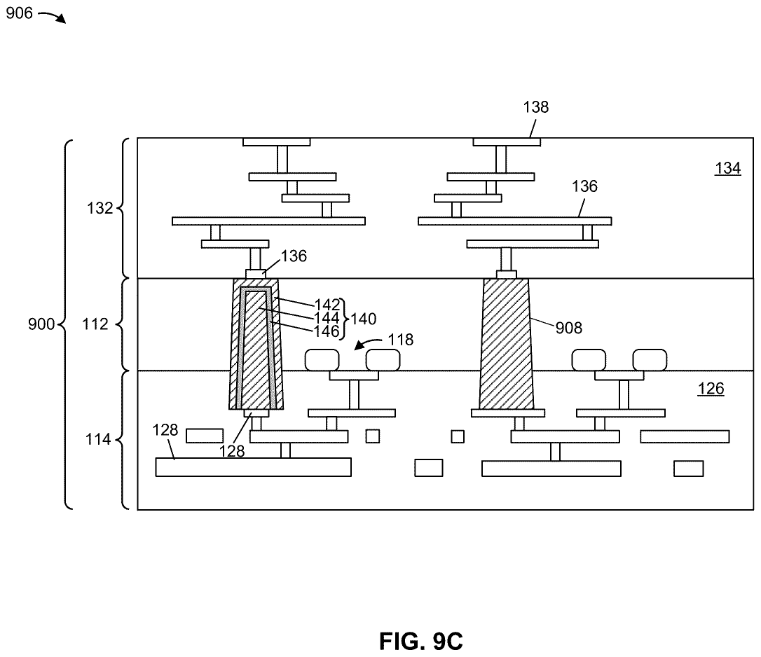

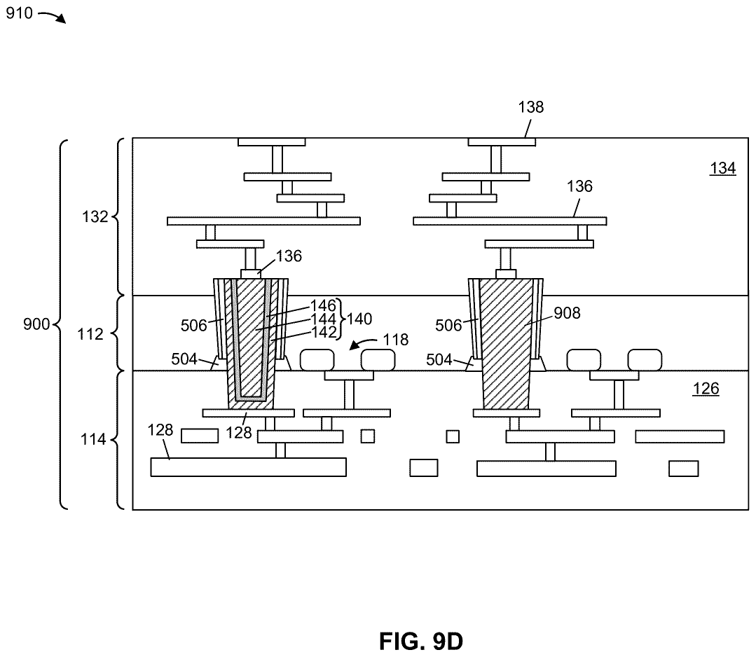

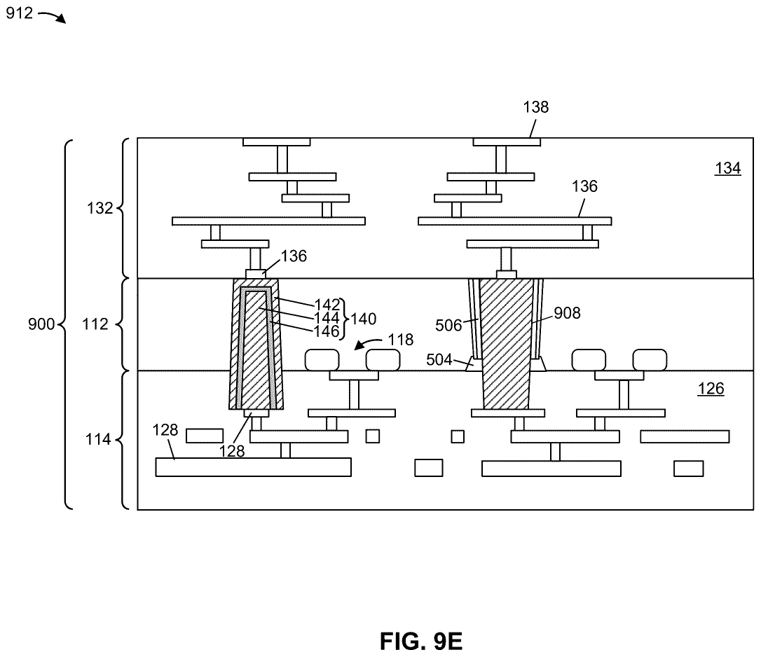

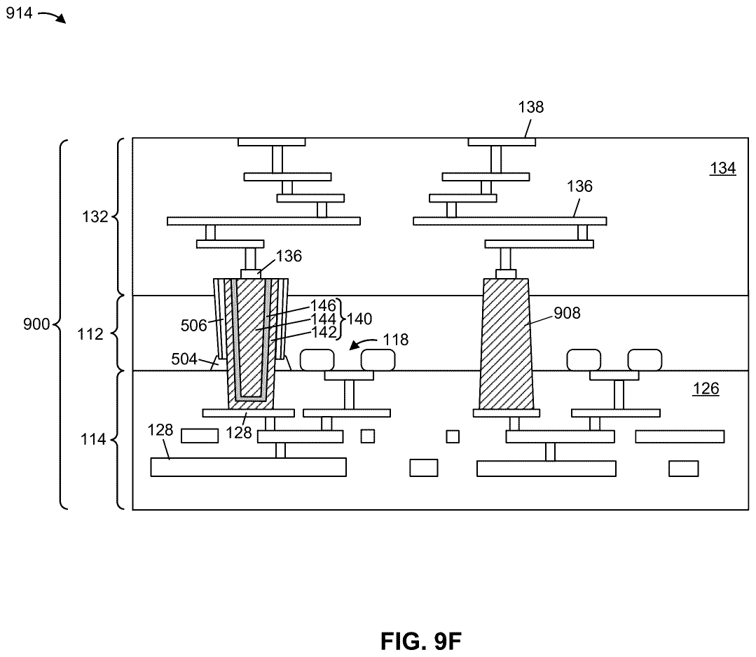

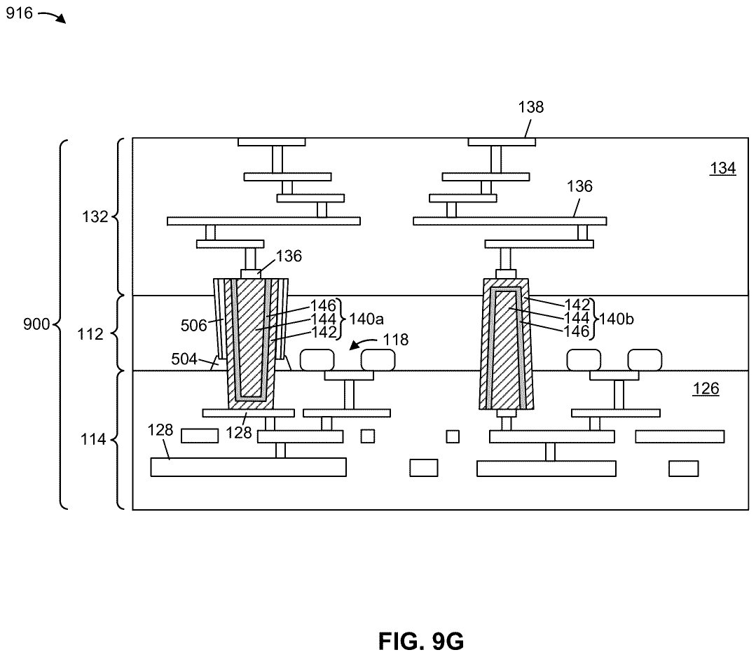

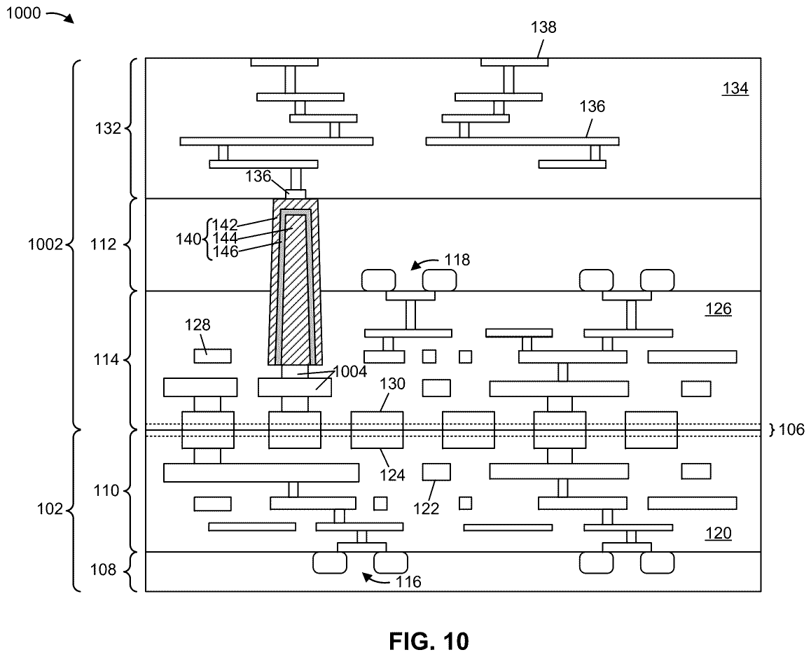

FIGS. 3A-3H are diagrams of an example implementation 300 of forming a semiconductor die described herein. In some implementations, the example implementation 300 includes an example process for forming the semiconductor die 104 or a portion thereof. In some implementations, one or more of the operations described in connection with the example implementation 300 may be performed to form another semiconductor die described herein, such as a semiconductor die 102, a semiconductor die 900 illustrated in one or more of FIGS. 9A-9G, a semiconductor die 1002 illustrated in FIG. 10, and/or another semiconductor die described herein. In some implementations, one or more semiconductor processing tools may be used to perform one or more of the operations described in connection with the example implementation 300, such as a deposition tool, an exposure tool, a developer tool, an etch tool, a planarization tool, a plating tool, and/or another type of semiconductor processing tool.

Turning to FIG. 3A, one or more of the operations in the example implementation 300 may be performed in connection with the semiconductor layer of the device layer 112 of the semiconductor die 104. The semiconductor layer of the device layer 112 may be provided in the form of a semiconductor wafer or another type of substrate layer.

As shown in FIG. 3B, the integrated circuit devices 118 may be formed in and/or on the device layer 112 of the semiconductor die 104. One or more semiconductor processing tools may be used to form one or more portions of the integrated circuit devices 118. For example, a deposition tool may be used to perform various deposition operations to deposit layers of the integrated circuit devices 118, and/or to deposit photoresist layers for etching the semiconductor layer of the device layer 112 and/or portions of the deposited layers. As another example, an exposure tool may be used to expose the photoresist layers to form patterns in the photoresist layers. As another example, a developer tool may develop the patterns in the photoresist layers. As another example, an etch tool may be used to etch the semiconductor layer and/or portions of the deposited layers to form the integrated circuit devices 118. As another example, a planarization tool may be used to planarize portions of the integrated circuit devices 118. As another example, an ion implantation tool may be used to implant ions in the semiconductor layer to dope portions of the semiconductor layer of the device layer 112 with one or more types of dopants (e.g., p-type dopants, n-type dopants).

As shown in FIG. 3C, a first portion of the interconnect layer 114 may be formed above the front side of the device layer 112. For example, a dielectric layer 126 of the interconnect layer 114 may be deposited above the front side of the device layer 112. A deposition tool may be used to deposit the dielectric layer 126 using a physical vapor deposition (PVD) technique, an atomic layer deposition (ALD) technique, a chemical vapor deposition (CVD) technique, an oxidation technique, and/or another suitable deposition technique. The dielectric layer 126 may be deposited in one or more deposition operations. In some implementations, a planarization tool may be used to perform a planarization operation (e.g., a chemical-mechanical planarization (CMP) operation) to planarize the dielectric layer 126 after the dielectric layer 126 is deposited.

As further shown in FIG. 3C, a recess 302 may be formed through the first portion of the interconnect layer 114 (e.g., through the dielectric layer 126) and into a portion of the substrate layer of the device layer 112. In some implementations, a pattern in a photoresist layer is used to etch the dielectric layer 126 and the device layer 112 to form the recess 302. In these implementations, a deposition tool may be used to form the photoresist layer on the dielectric layer 126 (e.g., using a spin-coating technique and/or another suitable deposition technique). An exposure tool may be used to expose the photoresist layer to a radiation source to pattern the photoresist layer. A developer tool may be used to develop and remove portions of the photoresist layer to expose the pattern. An etch tool may be used to etch the dielectric layer 126 and the device layer 112 based on the pattern to form the recess 302. In some implementations, the etch operation includes a dry etch operation (e.g., a plasma-based etch operation, a gas-based etch operation), a wet chemical etch operation, and/or another type of etch operation. In some implementations, a photoresist removal tool may be used to remove the remaining portions of the photoresist layer (e.g., using a chemical stripper, plasma ashing, and/or another technique). In some implementations, a hard mask layer is used as an alternative technique for forming the recess 302 based on a pattern.

As shown in FIG. 3C, the recess 302 may be formed to a depth corresponding to the dimension D1. As further shown in FIG. 3C, the lateral width of the top of the recess 302 may correspond to the dimension D2, and the lateral width of the bottom of the recess 302 may correspond to dimension D3. As indicated above, the lateral width of the top of the recess 302 may be greater than the lateral width of the bottom of the recess 302 (e.g., D2>D3) because of the etchant that is used to form the recess 302 being in contact with the dielectric layer 126 at the top of the recess 302 for a longer duration than being in contact with the device layer 112 at the bottom of the recess 302.

As shown in FIG. 3D, the bottom electrode 142 of a through-substrate capacitor structure 140 may be conformally deposited on the sidewalls and on the bottom surface of the recess 302. Thus, the bottom electrode 142 is formed on the sidewalls that correspond to the dielectric layer 126 of the interconnect layer 114 and that correspond to the substrate layer of the device layer 112. Moreover, the bottom electrode 142 is formed on the bottom surface that corresponds to the device layer 112. A deposition tool may be used to deposit the bottom electrode 142 using an ALD technique, a CVD technique, an electroplating technique, and/or another suitable deposition technique. In some implementations, the material of the bottom electrode 142 is also deposited along the top surface of the dielectric layer 126, as shown in the example in FIG. 3D.

As shown in FIG. 3E, the insulator layer 146 of the through-substrate capacitor structure 140 may be deposited on the bottom electrode 142 in the recess 302. The insulator layer 146 may be conformally deposited on the sidewalls and on the bottom surface of the recess 302. A deposition tool may be used to deposit the insulator layer 146 using an ALD technique, a CVD technique, and/or another suitable deposition technique. In some implementations, the material of the insulator layer 146 is also deposited along the top surface of the dielectric layer 126, as shown in the example in FIG. 3E.

As shown in FIG. 3F, the top electrode 144 of the through-substrate capacitor structure 140 may be deposited on the insulator layer 146 in the recess 302. In some implementations, the top electrode 144 is deposited such that the material of the top electrode 144 fills in the remaining area of the recess 302. In some implementations, the top electrode 144 is conformally deposited on the sidewalls and on the bottom surface of the recess 302. In these implementations, a dielectric plug may be subsequently formed in the recess 302, or additional bottom electrode(s) 142, additional insulator layer(s) 146, and additional top electrode(s) 144 may be formed in the recess 302.

As further shown in FIG. 3F, a planarization tool may be used to perform a planarization operation (e.g., a CMP operation) to remove excess material of the bottom electrode 142, excess material of the insulator layer 146, and/or excess material of the top electrode 144 from the top of the dielectric layer 126.

As shown in FIG. 3G, additional portions of the interconnect layer 114 may be formed above the device layer 112 (and above the through-substrate capacitor structure 140). One or more semiconductor processing tools may be used to form the interconnect layer 114 by forming one or more dielectric layers 126 and forming a plurality of conductive structures 128 in the dielectric layer(s) 126. For example, a deposition tool may be used to deposit a first layer of the dielectric layer(s) 126 (e.g., using a CVD technique, an ALD technique, a PVD technique, an oxidation technique, and/or another type of deposition technique), an etch tool may be used to remove portions of the first layer to form recesses in the first layer, and a deposition tool may be used to form a first layer (e.g., a via layer, a metallization layer) of one or more conductive structures 128 in the recesses (e.g., using a CVD technique, an ALD technique, a PVD technique, an electroplating technique, and/or another type of deposition technique). At least a portion of the first layer of conductive structures 128 may be electrically connected and/or physically connected with the integrated circuit devices 118 in the device layer 112 (e.g., directly connected or connected through contacts). Similar processing operations may be performed to form additional layers of the interconnect layer 114 until a sufficient or desired arrangement of conductive structures 128 is achieved.

As further shown in FIG. 3G, a conductive structure 128 in the interconnect layer 114 may be formed on the through-substrate capacitor structure 140 such that the conductive structure 128 is electrically coupled and/or physically coupled to the through-substrate capacitor structure 140. For example, the conductive structure 128 may be formed on the top electrode 144 of the through-substrate capacitor structure 140 such that the conductive structure 128 is electrically coupled and/or physically coupled to the top electrode 144.

As shown in FIG. 3H, the bonding pads 130 may be formed in a dielectric layer 126 of the interconnect layer 114. In some implementations, one or more bonding pads 130 may be electrically connected to one or more conductive structures 128 in the interconnect layer 114 by bonding vias 304.

As indicated above, FIGS. 3A-3H are provided as an example. Other examples may differ from what is described with regard to FIGS. 3A-3H.

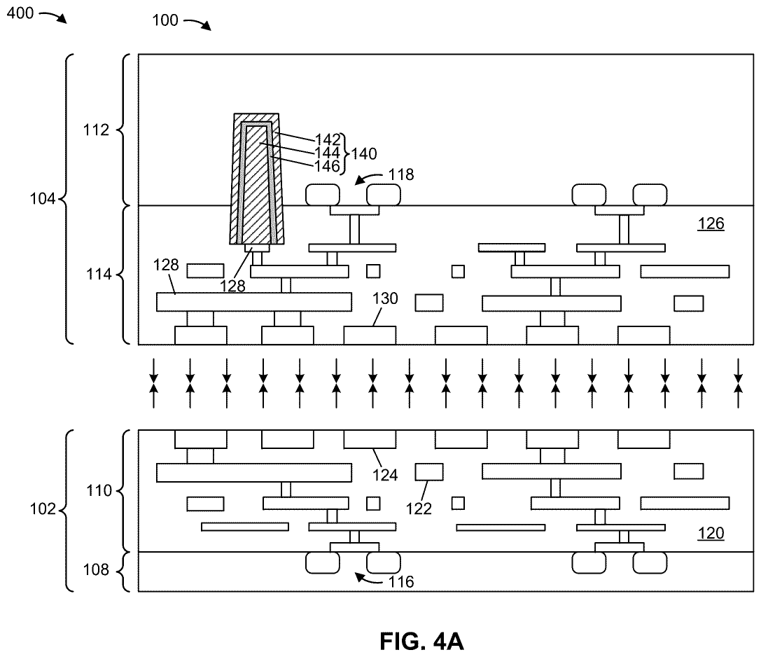

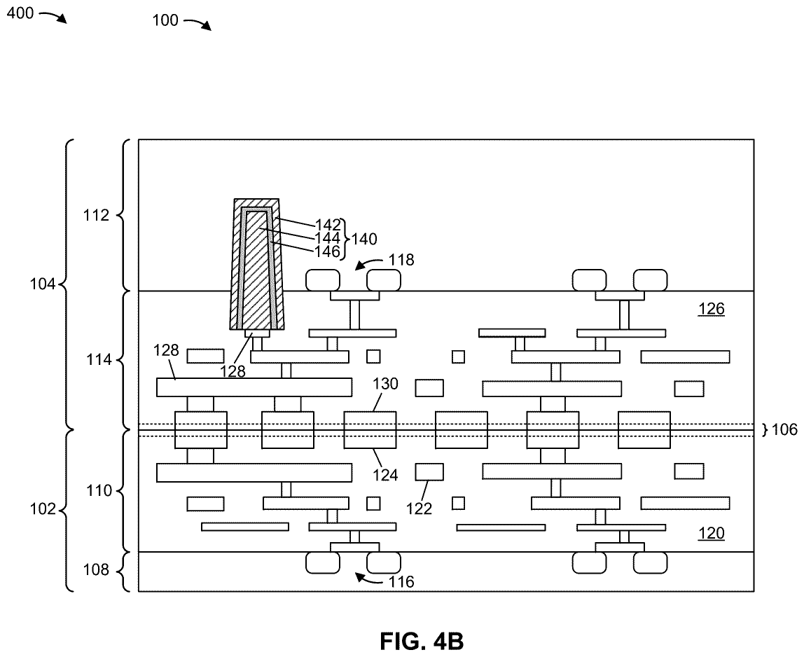

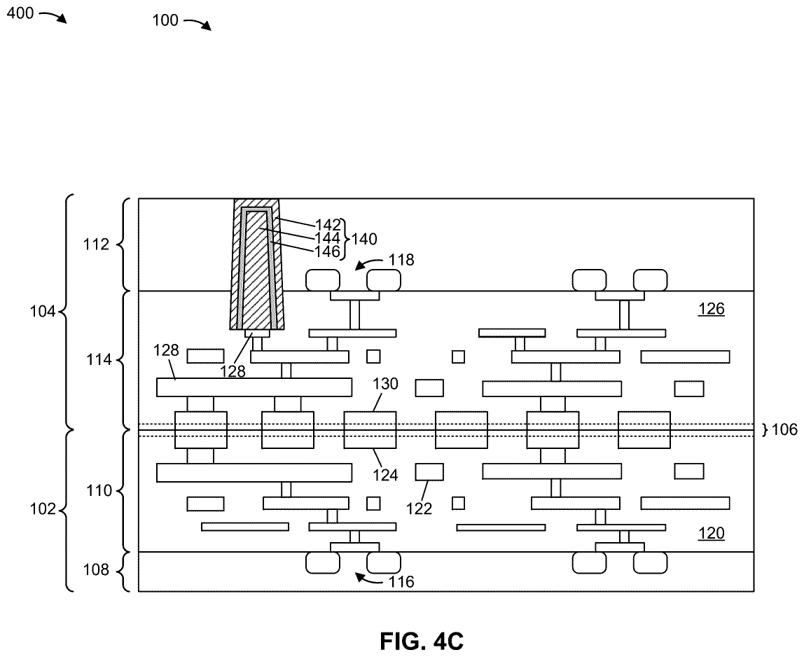

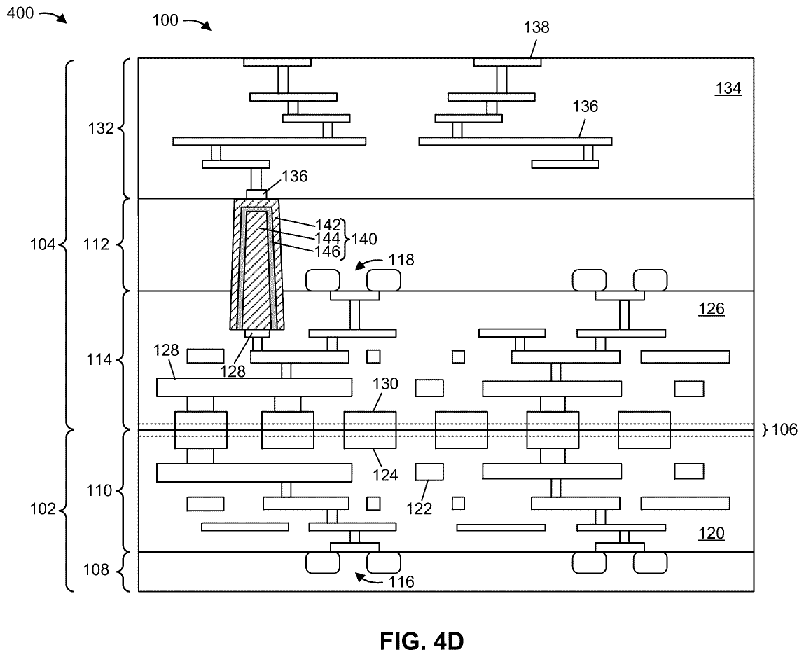

FIGS. 4A-4D are diagrams of an example implementation 400 of forming a semiconductor package described herein. For example, the example implementation 400 may include an example of forming a semiconductor package 100. In some implementations, one or more of the operations described in connection with the example implementation 400 may be performed to form another semiconductor die package described herein, such as a semiconductor package 1000 illustrated in FIG. 10, among other examples. In some implementations, one or more semiconductor processing tools may be used to perform one or more of the operations described in connection with the example implementation 400, such as bonding tool, a deposition tool, an exposure tool, a developer tool, an etch tool, a planarization tool, a plating tool, and/or another type of semiconductor processing tool.

As shown in FIGS. 4A and 4B, a bonding operation is performed to bond the semiconductor die 102 and the semiconductor die 104 at the bonding interface 106 such that the semiconductor die 102 and the semiconductor die 104 are vertically arranged or stacked in the semiconductor package 100. The semiconductor die 102 and the semiconductor die 104 may be vertically arranged or stacked in a wafer on wafer (WoW) configuration, a die on wafer configuration, a die on die configuration, and/or another direct bonding configuration. A bonding tool may be used to perform the bonding operation to bond the semiconductor die 102 and the semiconductor die 104 at the bonding interface 106. The bonding operation may include forming a direct bond between the semiconductor die 102 and the semiconductor die 104 through a direct physical connection of the bonding pads 124 of the semiconductor die 102 with the bonding pads 130 of the semiconductor die 104, and through a direct physical connection of one or more of the dielectric layers 120 of the semiconductor die 102 with one or more dielectric layers 126 of the semiconductor die 104.

As shown in FIG. 4C, back side processing may be performed on the back side of the device layer 112 after bonding the semiconductor dies 102 and 104 at the bonding interface 106. The back side processing may include using a planarization tool (e.g., a wafer grinding tool) to perform a planarization operation (e.g., a wafer grinding operation) to remove material from the back side of the device layer 112. The through-substrate capacitor structure 140 may be formed partially into the device layer 112. Thus, after bonding, the through-substrate capacitor structure 140 does not extend all the way through the device layer 112 to the back side of the device layer 112. Accordingly, the planarization operation may be performed to remove material from the back side of the device layer 112 to expose the bottom of the through-substrate capacitor structure 140 (e.g., the portion of the bottom electrode 142 at the bottom of the through-substrate capacitor structure 140) through the device layer 112. The planarization operation may result in the bottom of the through-substrate capacitor structure 140 being approximately co-planar with the back side surface of the device layer 112.

As shown in FIG. 4D, the interconnect layer 132 may be formed above the back side of the device layer 112. One or more semiconductor processing tools may be used to form the interconnect layer 132 by forming one or more dielectric layers 134 and forming a plurality of conductive structures 136 in the dielectric layer(s) 134. For example, a deposition tool may be used to deposit a first layer of the dielectric layer(s) 134 (e.g., using a CVD technique, an ALD technique, a PVD technique, an oxidation technique, and/or another type of deposition technique), an etch tool may be used to remove portions of the first layer to form recesses in the first layer, and a deposition tool may be used to form a first layer (e.g., a via layer, a metallization layer) of one or more conductive structures 136 in the recesses (e.g., using a CVD technique, an ALD technique, a PVD technique, an electroplating technique, and/or another type of deposition technique). Similar processing operations may be performed to form additional layers of the interconnect layer 132 until a sufficient or desired arrangement of conductive structures 136 is achieved.

As further shown in FIG. 4D, one or more of the conductive structures 136 in the interconnect layer 132 may be formed on the bottom of the through-substrate capacitor structure 140. For example, a conductive structure 136 may be formed on a portion of the bottom electrode 142 of the through-substrate capacitor structure 140 that is exposed through the back side of the device layer 112. The conductive structure 136 may be electrically connected and/or physically connected with the bottom electrode 142 of the through-substrate capacitor structure 140.

As further shown in FIG. 4D, the connection structures 138 of the interconnect layer 132 may be formed in a dielectric layer 134. In some implementations, one or more connection structures 138 may be electrically connected to one or more conductive structures 136 in the interconnect layer 132.

As indicated above, FIGS. 4A-4D are provided as an example. Other examples may differ from what is described with regard to FIGS. 4A-4D.

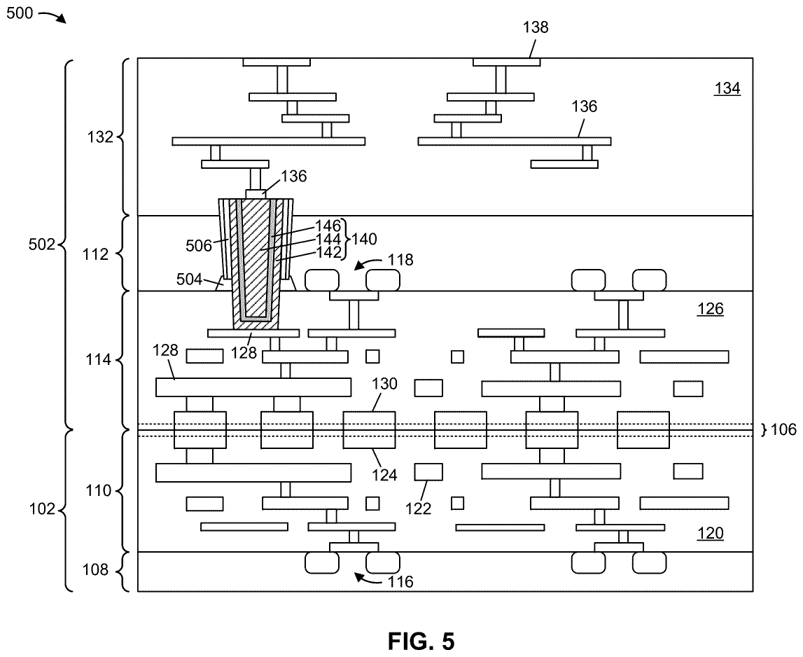

FIG. 5 is a diagram of an example semiconductor package 500 described herein. FIG. 5 illustrates a cross-section view of the semiconductor package 500. As shown in FIG. 5, the semiconductor package 500 includes a similar combination and arrangement of layers and/or structures as the semiconductor package 100 illustrated in FIG. 1. However, the semiconductor package 500 includes a semiconductor die 502 as opposed to the semiconductor die 104.

As shown in FIG. 5, the semiconductor die 502 is similar to the semiconductor die 104, and includes a device layer 112 (e.g., a semiconductor layer or substrate layer), an interconnect layer 114 on a first side (e.g., a front side) of the device layer 112, an interconnect layer 132 on a second side (e.g., a back side) of the device layer 112 vertically opposite the first side, and a through-substrate capacitor structure 140 that extends through the device layer 112 and into a portion of the interconnect layer 114.

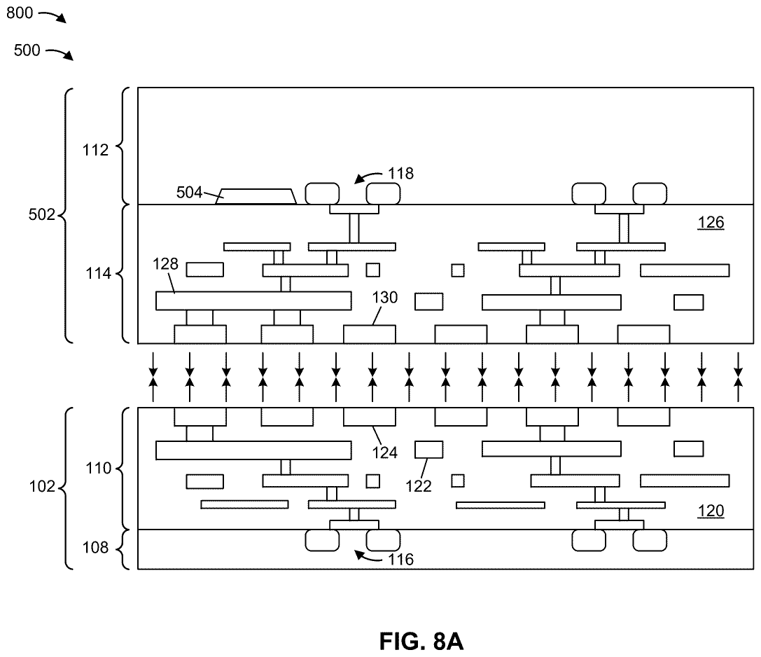

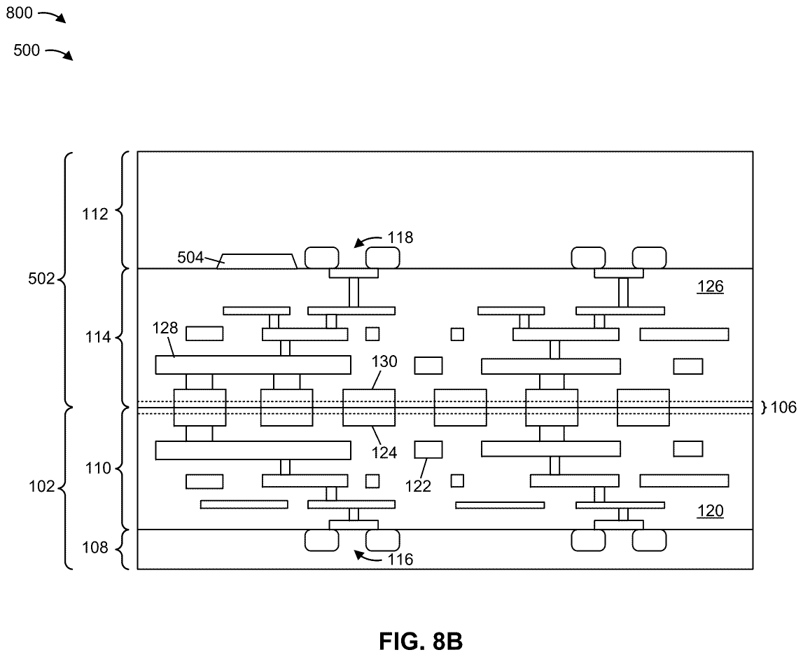

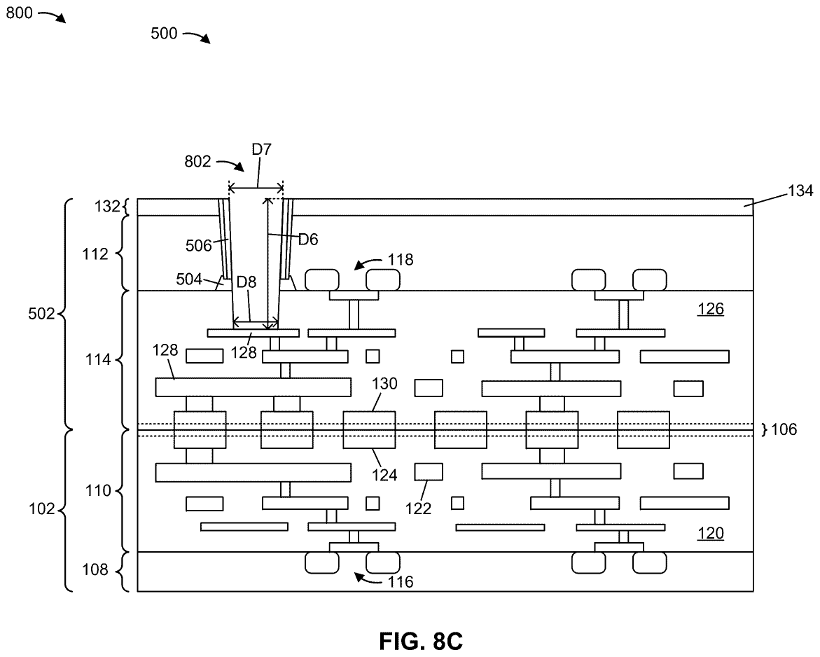

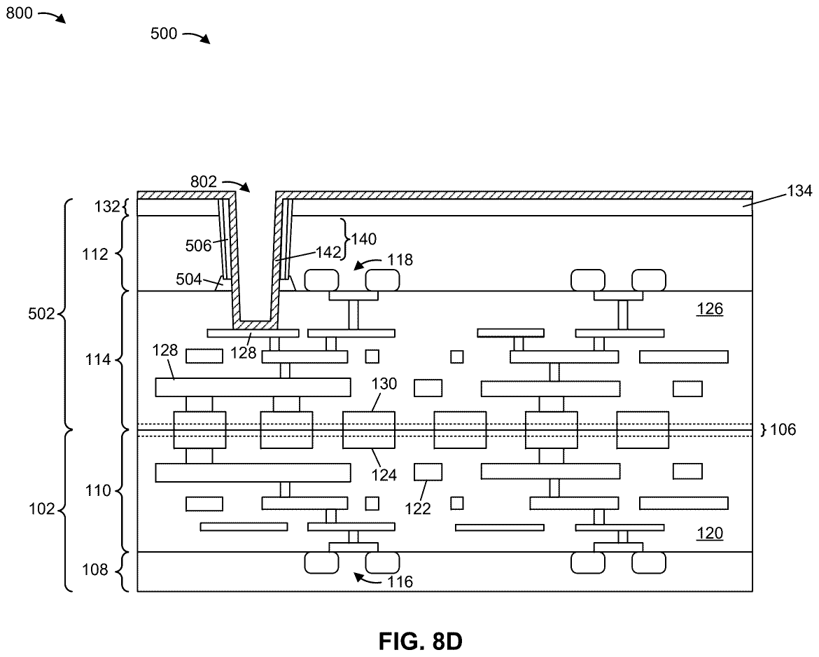

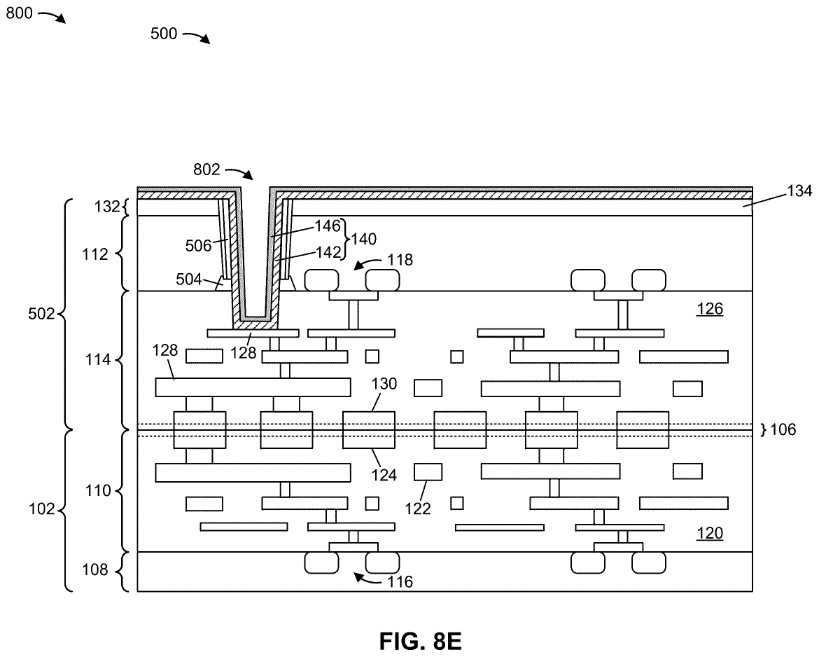

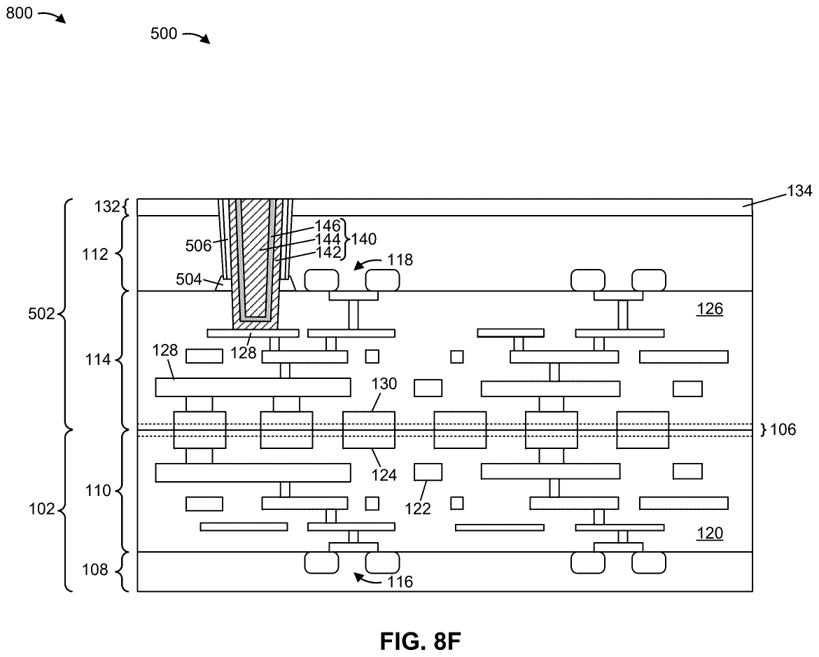

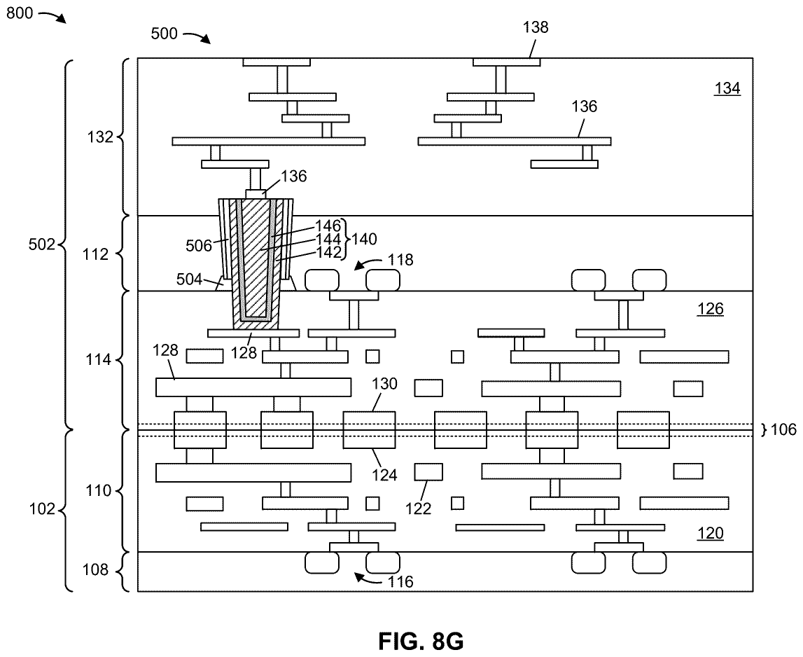

However, in the semiconductor die 502, the through-substrate capacitor structure 140 is formed by a different set of processing operations compared to the through-substrate capacitor structure 140 in the semiconductor die 104. In particular, the through-substrate capacitor structure 140 in the semiconductor die 104 is formed during front side processing of the semiconductor die 104 (e.g., the through-substrate capacitor structure 140 is formed into the front side of the device layer 112 of the semiconductor die 104 during formation of the interconnect layer 114 on the front side of the device layer 112). Conversely, the through-substrate capacitor structure 140 in the semiconductor die 502 is formed during back side processing of the semiconductor die 502. As illustrated in FIGS. 8A-8G, the through-substrate capacitor structure 140 is formed into the back side of the device layer 112 of the semiconductor die 502 during formation of the interconnect layer 132 on the back side of the device layer 112 of the semiconductor die 502.

As a result of the different process for forming the through-substrate capacitor structure 140 in the semiconductor die 502, the orientation of the through-substrate capacitor structure 140 in the semiconductor die 502 is different from the orientation of the through-substrate capacitor structure 140 in the semiconductor die 104. For example, in the semiconductor die 104, the top of the through-substrate capacitor structure 140 is located in the interconnect layer 114, and the top electrode 144 at the top of the through-substrate capacitor structure 140 is electrically coupled to a conductive structure 128 in the interconnect layer 114. The bottom of the through-substrate capacitor structure 140 in the semiconductor die 104 is located at the interface between the device layer 112 and the interconnect layer 132, and the bottom electrode 142 at the bottom of the through-substrate capacitor structure 140 is electrically coupled to a conductive structure 136 in the interconnect layer 132.

Conversely, in the semiconductor die 502, the bottom of the through-substrate capacitor structure 140 is located in the interconnect layer 114, and the bottom electrode 142 at the bottom of the through-substrate capacitor structure 140 is electrically coupled to a conductive structure 128 in the interconnect layer 114. The top of the through-substrate capacitor structure 140 in the semiconductor die 502 is located in the interconnect layer 132, and the top electrode 144 at the top of the through-substrate capacitor structure 140 is electrically coupled to a conductive structure 136 in the interconnect layer 132.

As further shown in FIG. 5, the through-substrate capacitor structure 140 may further extend through a shallow trench isolation (STI) region 504 that is included in the substrate layer of the device layer 112. The STI region 504 may include one or more dielectric materials such as a silicon oxide material (SiOₓ such as SiO₂), a silicon nitride material (SiₓN_{y} such Si₃N₄), and/or another suitable dielectric material.

The through-substrate capacitor structure 140 may include a metal material (e.g., copper (Cu)) that is susceptible to diffusion into the substrate layer of the device layer 112.

Accordingly, and as further shown in FIG. 5, one or more liners 506 may be included between the through-substrate capacitor structure 140 and the substrate layer of the device layer 112 to provide a diffusion barrier and/or to provide electrical isolation between the through-substrate capacitor structure 140 and the integrated circuit devices 118 in the device layer 112, among other examples. The one or more liners 506 may include a high-k dielectric liner, a low-k dielectric liner, and/or another type of liner.

The STI region 504 and the liner(s) 506 enable integrated circuit devices 118 to be positioned closer to the through-substrate capacitor structure 140 than if no STI and/or no liners were included around the through-substrate capacitor structure 140. This may enable an increased integrated circuit device density to be achieved in the device layer 112. Moreover, an integrated circuit device 118 (e.g., adjacent to the through-substrate capacitor structure 140) may be electrically connected to the through-substrate capacitor structure 140 (e.g., through one or more conductive structures 128 in the interconnect layer 114) to form a memory cell (e.g., a DRAM cell) and/or to form another type of device (or a portion thereof). For example, the through-substrate capacitor structure 140 may be an overflow capacitor for a lateral overflow integration capacitor (LOFIC) pixel sensor, and an integrated circuit device 118 (of the LOFIC pixel sensor) adjacent to the through-substrate capacitor structure 140 may be coupled to the through-substrate capacitor structure 140. The integrated circuit device 118 may be a transfer gate of the LOFIC pixel sensor, and the through-substrate capacitor structure 140 may be electrically connected to a source/drain of the transfer gate. Alternatively, the integrated circuit device 118 may be a source-follower gate, and the through-substrate capacitor structure 140 may be electrically connected to the gate of the source-follower gate.

As indicated above, FIG. 5 is provided as an example. Other examples may differ from what is described with regard to FIG. 5.

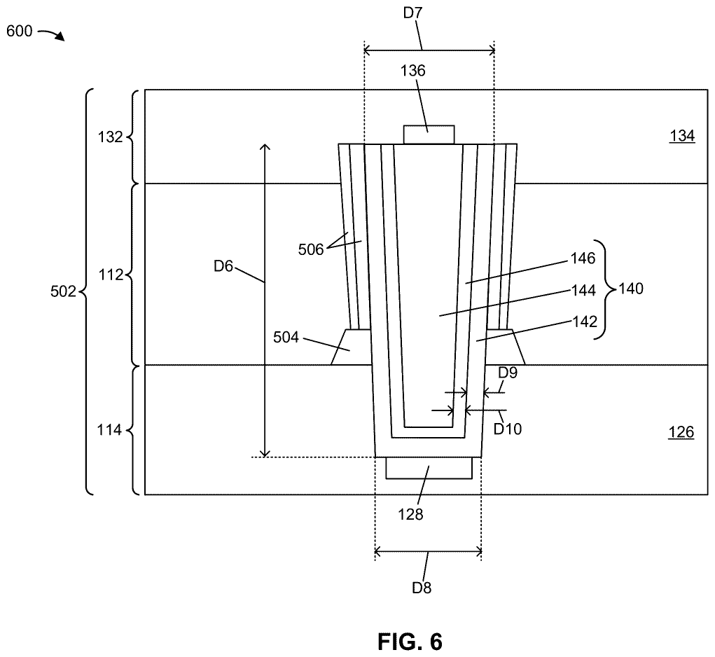

FIG. 6 is a diagram of an example implementation 600 of a through-substrate capacitor structure 140 in the semiconductor die 502 described herein. As shown in FIG. 6, the through-substrate capacitor structure 140 may have one or more example dimensions.

As shown in FIG. 6, an example dimension D6 corresponds to a vertical height of the through-substrate capacitor structure 140. In some implementations, the vertical height of the through-substrate capacitor structure 140 may be included in a range of approximately 10 microns to approximately 100 microns. However, other values for the range are within the scope of the present disclosure.

Another example dimension D7 corresponds to a top width (or top critical dimension (CD)) of the through-substrate capacitor structure 140 in the interconnect layer 132, and another example dimension D8 corresponds to a bottom width (or bottom CD) of the through-substrate capacitor structure 140 in the interconnect layer 114. The top width of the through-substrate capacitor structure 140 may be greater than the bottom width of the through-substrate capacitor structure 140 (e.g., D7>D8). The recess in which the through-substrate capacitor structure 140 is formed may be formed from the back side of the device layer 112. The top of the recess may have a greater width than the bottom of the recess because an etchant that was used to form the recess was in contact with the dielectric layer(s) 134 for a longer duration than the dielectric layer(s) 126, and therefore a greater amount of lateral etching may occur at the top of the recess in the dielectric layer(s) 134 in the interconnect layer 132 than at the bottom of the recess in the dielectric layer(s) 126 in the interconnect layer 114. Accordingly, the through-substrate capacitor structure 140 may have a similar cross-sectional profile where the top of the through-substrate capacitor structure 140 has a greater width (e.g., dimension D7) than the bottom of the through-substrate capacitor structure 140 (e.g., dimension D8).

In some implementations, the top width (e.g., the dimension D7) and the bottom width (e.g., the dimension D8) of the through-substrate capacitor structure 140 may each be included in a range of approximately 1 micron to approximately 10 microns. The top width may be closer to the top of the range than the bottom width, which may be closer to the bottom of the range than the top width. However, other values for the range are within the scope of the present disclosure.

The through-substrate capacitor structure 140 may have a high aspect ratio (e.g., a ratio of the height to the top width (e.g., D6:D7)). The high aspect ratio of the through-substrate capacitor structure 140 enables the height of the through-substrate capacitor structure 140 (e.g., the dimension D6) to be increased (which increases the capacitance of the through-substrate capacitor structure 140) while maintaining a relatively small lateral footprint (e.g., dimension D7) for the through-substrate capacitor structure 140 (which enables a high density of structures to be achieved in the semiconductor die 104). For example, the aspect ratio of the through-substrate capacitor structure 140 may be included in a range of approximately 5:1 to approximately 15:1. However, other values for the range are within the scope of the present disclosure.

As further shown in FIG. 6, another example dimension D9 of the through-substrate capacitor structure 140 corresponds to a thickness of the bottom electrode 142. In some implementations, the thickness of the bottom electrode 142 is included in a range of approximately 0.5 microns to approximately 5 microns. However, other values for the range are within the scope of the present disclosure.

As further shown in FIG. 6, another example dimension D10 of the through-substrate capacitor structure 140 corresponds to a thickness of the insulator layer 146. In some implementations, the thickness of the insulator layer 146 is included in a range of approximately 10 angstroms to approximately 1000 angstroms. However, other values for the range are within the scope of the present disclosure.

As indicated above, FIG. 6 is provided as an example. Other examples may differ from what is described with regard to FIG. 6.

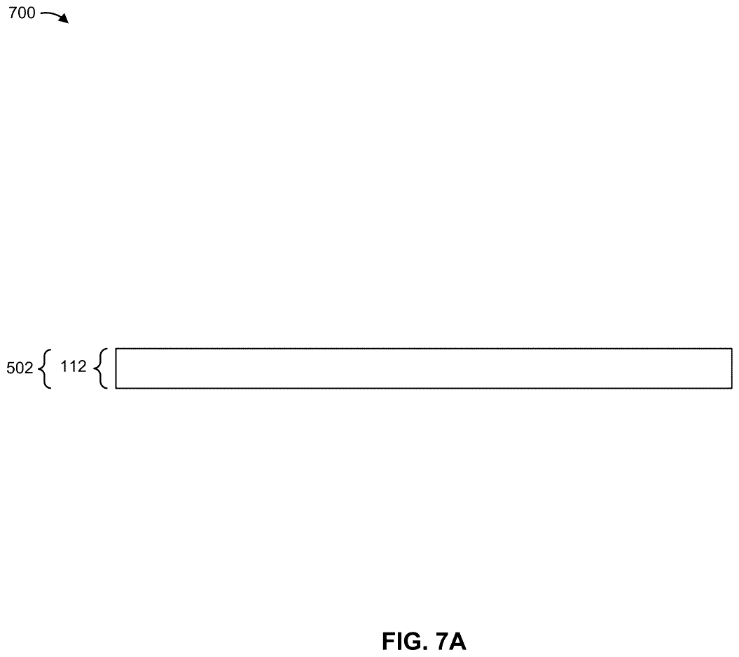

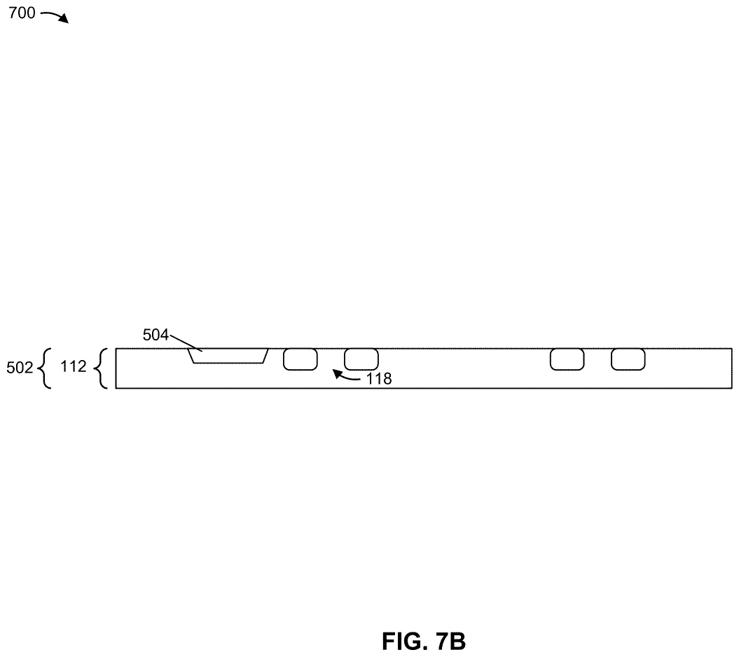

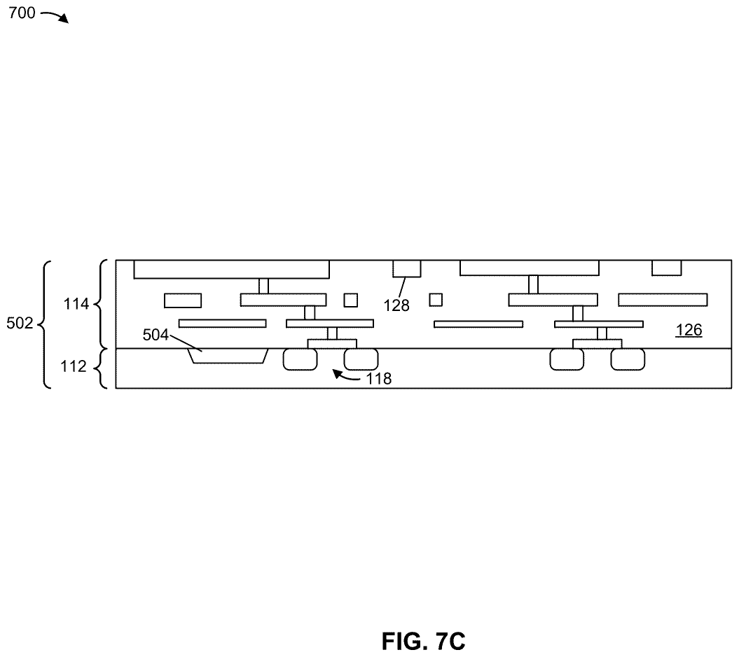

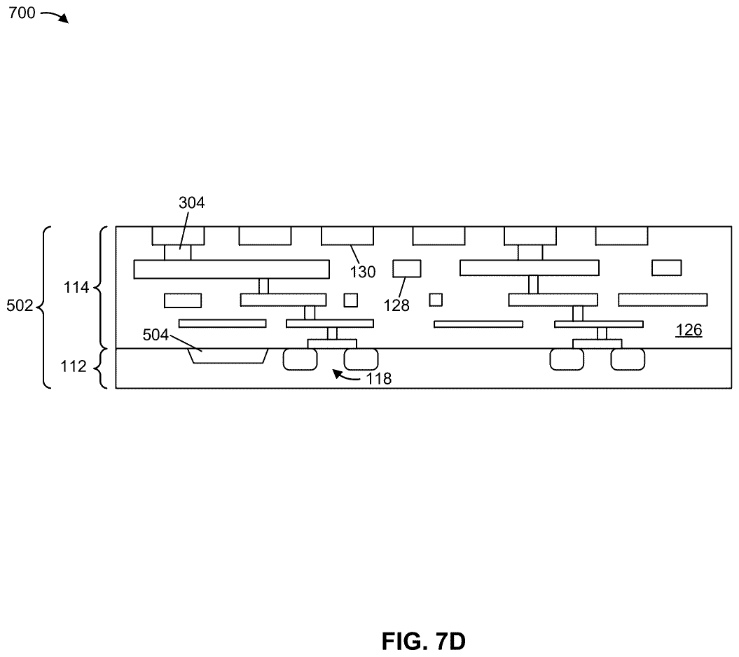

FIGS. 7A-7D are diagrams of an example implementation 700 of forming a semiconductor die described herein. In some implementations, the example implementation 700 includes an example process for forming the semiconductor die 502 or a portion thereof. In some implementations, one or more of the operations described in connection with the example implementation 700 may be performed to form another semiconductor die described herein, such as a semiconductor die 900 illustrated in one or more of FIGS. 9A-9G, a semiconductor die 1002 illustrated in FIG. 10, and/or another semiconductor die described herein. In some implementations, one or more semiconductor processing tools may be used to perform one or more of the operations described in connection with the example implementation 700, such as a deposition tool, an exposure tool, a developer tool, an etch tool, a planarization tool, a plating tool, and/or another type of semiconductor processing tool.

Turning to FIG. 7A, one or more of the operations in the example implementation 700 may be performed in connection with the semiconductor layer of the device layer 112 of the semiconductor die 502. The semiconductor layer of the device layer 112 may be provided in the form of a semiconductor wafer or another type of substrate layer.

As shown in FIG. 7B, the integrated circuit devices 118 may be formed in and/or on the device layer 112 of the semiconductor die 502. One or more semiconductor processing tools may be used to form one or more portions of the integrated circuit devices 118. For example, a deposition tool may be used to perform various deposition operations to deposit layers of the integrated circuit devices 118, and/or to deposit photoresist layers for etching the semiconductor layer of the device layer 112 and/or portions of the deposited layers. As another example, an exposure tool may be used to expose the photoresist layers to form patterns in the photoresist layers. As another example, a developer tool may develop the patterns in the photoresist layers. As another example, an etch tool may be used to etch the semiconductor layer and/or portions of the deposited layers to form the integrated circuit devices 118. As another example, a planarization tool may be used to planarize portions of the integrated circuit devices 118. As another example, an ion implantation tool may be used to implant ions in the semiconductor layer to dope portions of the semiconductor layer of the device layer 112 with one or more types of dopants (e.g., p-type dopants, n-type dopants).

As further shown in FIG. 7B, an STI region 504 may be formed in the device layer 112 of the semiconductor die 502. The STI region 504 may be formed in a recess in the device layer 112. In some implementations, a pattern in a photoresist layer is used to etch the device layer 112 to form the recess in the device layer 112. In these implementations, a deposition tool may be used to form the photoresist layer on the device layer 112. An exposure tool may be used to expose the photoresist layer to a radiation source to pattern the photoresist layer. A developer tool may be used to develop and remove portions of the photoresist layer to expose the pattern. An etch tool may be used to etch the device layer 112 based on the pattern to form the recess. In some implementations, the etch operation includes a plasma etch operation, a wet chemical etch operation, and/or another type of etch operation. In some implementations, a photoresist removal tool may be used to remove the remaining portions of the photoresist layer (e.g., using a chemical stripper, plasma ashing, and/or another technique). In some implementations, a hard mask layer is used as an alternative technique for etching the device layer 112 based on a pattern.

A deposition tool may be used to deposit the dielectric material of the STI region 504 in the recess using a CVD technique, an ALD technique, a PVD technique, an oxidation technique, and/or another suitable deposition technique. The dielectric material of the STI region 504 may be deposited in one or more deposition operations. In some implementations, a planarization tool may be used to perform a planarization operation (e.g., a CMP operation) to planarize the STI region 504 after the dielectric material of the STI region 504 is deposited.

As shown in FIG. 7C, the interconnect layer 114 may be formed above the front side of the device layer 112 (e.g., prior to formation of the through-substrate capacitor structure 140).

One or more semiconductor processing tools may be used to form the interconnect layer 114 by forming one or more dielectric layers 126 and forming a plurality of conductive structures 128 in the dielectric layer(s) 126. For example, a deposition tool may be used to deposit a first layer of the dielectric layer(s) 126 (e.g., using a CVD technique, an ALD technique, a PVD technique, an oxidation technique, and/or another type of deposition technique), an etch tool may be used to remove portions of the first layer to form recesses in the first layer, and a deposition tool may be used to form a first layer (e.g., a via layer, a metallization layer) of one or more conductive structures 128 in the recesses (e.g., using a CVD technique, an ALD technique, a PVD technique, an electroplating technique, and/or another type of deposition technique). At least a portion of the first layer of conductive structures 128 may be electrically connected and/or physically connected with the integrated circuit devices 118 in the device layer 112 (e.g., directly connected or connected through contacts). Similar processing operations may be performed to form additional layers of the interconnect layer 114 until a sufficient or desired arrangement of conductive structures 128 is achieved.

As shown in FIG. 7D, the bonding pads 130 may be formed in a dielectric layer 126 of the interconnect layer 114. In some implementations, one or more bonding pads 130 may be electrically connected to one or more conductive structures 128 in the interconnect layer 114 by bonding vias 304.

As indicated above, FIGS. 7A-7D are provided as an example. Other examples may differ from what is described with regard to FIGS. 7A-7D.

FIGS. 8A-8G are diagrams of an example implementation 800 of forming a semiconductor package described herein. For example, the example implementation 800 may include an example of forming a semiconductor package 500. In some implementations, one or more of the operations described in connection with the example implementation 800 may be performed to form another semiconductor die package described herein, such as a semiconductor package 1000 illustrated in FIG. 10, among other examples. In some implementations, one or more semiconductor processing tools may be used to perform one or more of the operations described in connection with the example implementation 800, such as bonding tool, a deposition tool, an exposure tool, a developer tool, an etch tool, a planarization tool, a plating tool, and/or another type of semiconductor processing tool.

As shown in FIGS. 8A and 8B, a bonding operation is performed to bond the semiconductor die 102 and the semiconductor die 502 at the bonding interface 106 such that the semiconductor die 102 and the semiconductor die 502 are vertically arranged or stacked in the semiconductor package 500. The semiconductor die 102 and the semiconductor die 502 may be vertically arranged or stacked in a wafer on wafer (WoW) configuration, a die on wafer configuration, a die on die configuration, and/or another direct bonding configuration. A bonding tool may be used to perform the bonding operation to bond the semiconductor die 102 and the semiconductor die 502 at the bonding interface 106. The bonding operation may include forming a direct bond between the semiconductor die 102 and the semiconductor die 502 through a direct physical connection of the bonding pads 124 of the semiconductor die 102 with the bonding pads 130 of the semiconductor die 502, and through a direct physical connection of one or more of the dielectric layers 120 of the semiconductor die 102 with one or more dielectric layers 126 of the semiconductor die 502.

As shown in FIG. 8C, back side processing may be performed on the back side of the device layer 112 after bonding the semiconductor dies 102 and 502 at the bonding interface 106. The back side processing may include forming a first portion of the interconnect layer 132 above the back side of the device layer 112. For example, a dielectric layer 134 of the interconnect layer 132 may be deposited above the back side of the device layer 112. A deposition tool may be used to deposit the dielectric layer 134 using a PVD technique, an ALD technique, a CVD technique, an oxidation technique, and/or another suitable deposition technique. The dielectric layer 134 may be deposited in one or more deposition operations. In some implementations, a planarization tool may be used to perform a planarization operation (e.g., a CMP operation) to planarize the dielectric layer 134 after the dielectric layer 134 is deposited.

As further shown in FIG. 8C, a recess 802 may be formed through the first portion of the interconnect layer 132 (e.g., through the dielectric layer 134), through the substrate layer of the device layer 112, and into a portion of the interconnect layer 114 (e.g., into a dielectric layer 126 of the interconnect layer 114). In some implementations, a pattern in a photoresist layer is used to etch the dielectric layer 134, the substrate layer of the device layer 112, and/or the dielectric layer 126 to form the recess 802. In these implementations, a deposition tool may be used to form the photoresist layer on the dielectric layer 134 (e.g., using a spin-coating technique and/or another suitable deposition technique). An exposure tool may be used to expose the photoresist layer to a radiation source to pattern the photoresist layer. A developer tool may be used to develop and remove portions of the photoresist layer to expose the pattern. An etch tool may be used to etch the dielectric layer 134, the substrate layer of the device layer 112, and/or the dielectric layer 126 based on the pattern to form the recess 802. In some implementations, a hard mask layer is used as an alternative technique for forming the recess 802 based on a pattern.

In some implementations, the etch operation includes a dry etch operation (e.g., a plasma-based etch operation, a gas-based etch operation), a wet chemical etch operation, and/or another type of etch operation. In some implementations, a photoresist removal tool may be used to remove the remaining portions of the photoresist layer (e.g., using a chemical stripper, plasma ashing, and/or another technique). In some implementations, a plurality of etch operations may be performed to form the recess 802. For example, a first etch operation may be performed to form the recess 802 into the device layer 112 to the STI region 504, and a second etch operation may be performed to etch through the STI region 504 and into the dielectric layer 126 to an underlying conductive structure 128 in the interconnect layer 114.

As shown in FIG. 8C, the recess 802 may be formed to a depth corresponding to the dimension D6. As further shown in FIG. 8C, the lateral width of the top of the recess 802 may correspond to the dimension D7, and the lateral width of the bottom of the recess 802 may correspond to dimension D8. As indicated above, the lateral width of the top of the recess 802 may be greater than the lateral width of the bottom of the recess 802 (e.g., D7>D8) because of the etchant that is used to form the recess 802 being in contact with the dielectric layer 134 at the top of the recess 802 for a longer duration than being in contact with the dielectric layer 126 at the bottom of the recess 802.

As further shown in FIG. 8C, one or more liners 506 may be formed on the sidewalls of the recess 802 (e.g., the portions of the sidewalls corresponding to the substrate layer of the device layer 112). A deposition tool may be used to conformally deposit the liner(s) 506 using a CVD technique, an ALD technique, and/or another deposition technique.

As shown in FIG. 8D, the bottom electrode 142 of a through-substrate capacitor structure 140 may be conformally deposited on the sidewalls and on the bottom surface of the recess 802. The bottom of the recess 802 may correspond to a conductive structure 128 in the interconnect layer 114 that is exposed through the recess 802, and therefore the bottom electrode 142 is formed on the conductive structure 128 such that the bottom electrode 142 is electrically coupled and/or physically coupled to the conductive structure 128. A deposition tool may be used to deposit the bottom electrode 142 using an ALD technique, a CVD technique, an electroplating technique, and/or another suitable deposition technique. In some implementations, the material of the bottom electrode 142 is also deposited along the top surface of the dielectric layer 126, as shown in the example in FIG. 8D.

As shown in FIG. 8E, the insulator layer 146 of the through-substrate capacitor structure 140 may be deposited on the bottom electrode 142 in the recess 802. The insulator layer 146 may be conformally deposited on the sidewalls and on the bottom surface of the recess 802. A deposition tool may be used to deposit the insulator layer 146 using an ALD technique, a CVD technique, and/or another suitable deposition technique. In some implementations, the material of the insulator layer 146 is also deposited along the top surface of the dielectric layer 126, as shown in the example in FIG. 8E.

As shown in FIG. 8F, the top electrode 144 of the through-substrate capacitor structure 140 may be deposited on the insulator layer 146 in the recess 802. In some implementations, the top electrode 144 is deposited such that the material of the top electrode 144 fills in the remaining area of the recess 802. In some implementations, the top electrode 144 is conformally deposited on the sidewalls and on the bottom surface of the recess 802. In these implementations, a dielectric plug may be subsequently formed in the recess 802, or additional bottom electrode(s) 142, additional insulator layer(s) 146, and additional top electrode(s) 144 may be formed in the recess 802.

As further shown in FIG. 8F, a planarization tool may be used to perform a planarization operation (e.g., a CMP operation) to remove excess material of the bottom electrode 142, excess material of the insulator layer 146, and/or excess material of the top electrode 144 from the top of the dielectric layer 134.

As shown in FIG. 8G, additional portions of the interconnect layer 132 may be formed above the back side of the device layer 112 (and above the through-substrate capacitor structure 140). One or more semiconductor processing tools may be used to form the interconnect layer 132 by forming one or more dielectric layers 134 and forming a plurality of conductive structures 136 in the dielectric layer(s) 134. For example, a deposition tool may be used to deposit a first layer of the dielectric layer(s) 134 (e.g., using a CVD technique, an ALD technique, a PVD technique, an oxidation technique, and/or another type of deposition technique), an etch tool may be used to remove portions of the first layer to form recesses in the first layer, and a deposition tool may be used to form a first layer (e.g., a via layer, a metallization layer) of one or more conductive structures 136 in the recesses (e.g., using a CVD technique, an ALD technique, a PVD technique, an electroplating technique, and/or another type of deposition technique). Similar processing operations may be performed to form additional layers of the interconnect layer 132 until a sufficient or desired arrangement of conductive structures 136 is achieved.

As further shown in FIG. 8G, a conductive structure 136 in the interconnect layer 132 may be formed on the through-substrate capacitor structure 140 such that the conductive structure 136 is electrically coupled and/or physically coupled to the through-substrate capacitor structure 140. For example, the conductive structure 136 may be formed on the top electrode 144 of the through-substrate capacitor structure 140 such that the conductive structure 136 is electrically coupled and/or physically coupled to the top electrode 144.

As further shown in FIG. 8G, the connection structures 138 of the interconnect layer 132 may be formed in a dielectric layer 134. In some implementations, one or more connection structures 138 may be electrically connected to one or more conductive structures 136 in the interconnect layer 132.

As indicated above, FIGS. 8A-8G are provided as an example. Other examples may differ from what is described with regard to FIGS. 8A-8G.

FIG. 9A9G are diagrams of examples of a semiconductor die 900 described herein.

The semiconductor die 900 may be a standalone semiconductor die that includes both front side and back side interconnect layers (e.g., interconnect layers 114 and 132), and a through-substrate capacitor structure 140 extending through the device layer 112 of the semiconductor die 900 and electrically coupled to conductive structures (e.g., conductive structures 128 and 136) in the front side and back side interconnect layers.

As shown in FIG. 9A, an example 902 of the semiconductor die 900 is similar to the semiconductor die 104, and includes a device layer 112 (e.g., a semiconductor layer or substrate layer), an interconnect layer 114 on a first side (e.g., a front side) of the device layer 112, an interconnect layer 132 on a second side (e.g., a back side) of the device layer 112 vertically opposite the first side, and a through-substrate capacitor structure 140 that extends through the device layer 112 and into a portion of the interconnect layer 114. The example 902 of the semiconductor die 900 may be formed by similar processing operations described in connection with FIGS. 3A-3H and/or 4A-4D.

As shown in FIG. 9B, an example 904 of the semiconductor die 900 is similar to the semiconductor die 502, and includes a device layer 112 (e.g., a semiconductor layer or substrate layer), an interconnect layer 114 on a first side (e.g., a front side) of the device layer 112, an interconnect layer 132 on a second side (e.g., a back side) of the device layer 112 vertically opposite the first side, and a through-substrate capacitor structure 140 that extends through the device layer 112 and an STI region 504 in the device layer 112. Opposing ends of the through-substrate capacitor structure 140 extend into a portion of the interconnect layer 114 and into a portion of the interconnect layer 132. The example 904 of the semiconductor die 900 may be formed by processing operations similar to those described in connection with FIGS. 7A-7D and/or 8A-8G.

As shown in FIG. 9C, an example 906 of the semiconductor die 900 is similar to the semiconductor die 104, and includes a device layer 112 (e.g., a semiconductor layer or substrate layer), an interconnect layer 114 on a first side (e.g., a front side) of the device layer 112, an interconnect layer 132 on a second side (e.g., a back side) of the device layer 112 vertically opposite the first side, and a through-substrate capacitor structure 140 that extends through the device layer 112 and into a portion of the interconnect layer 114. The example 906 of the semiconductor die 900 may be formed by similar processing operations described in connection with FIGS. 3A-3H and/or 4A-4D.

However, in the example 906, the semiconductor die 900 includes a TSV structure 908 that extends through the device layer and into a portion of the interconnect layer 114. The TSV structure 908 and the through-substrate capacitor structure 140 may both be formed from the front side of the device layer 112 (e.g., during formation of the interconnect layer 114).

In some implementations, the bottom electrode 142 and the top electrode 144 of the through-substrate capacitor structure 140 and the TSV structure 908 are formed of the same material such as copper (Cu). In some implementations, the bottom electrode 142 and the top electrode 144 of the through-substrate capacitor structure 140 are formed of copper (Cu), and the TSV structure 908 are formed of a different material such as tungsten (W).

In some implementations, the TSV structure 908 and the through-substrate capacitor structure 140 may be formed at different times. For example, the process loop for forming the TSV structure 908 may be performed first, followed by the process loop for forming the through-substrate capacitor structure 140. As another example, the process loop for forming the through-substrate capacitor structure 140 may be performed first, followed by the process loop for forming the TSV structure 908.

As shown in FIG. 9D, an example 910 of the semiconductor die 900 is similar to the semiconductor die 502, and includes a device layer 112 (e.g., a semiconductor layer or substrate layer), an interconnect layer 114 on a first side (e.g., a front side) of the device layer 112, an interconnect layer 132 on a second side (e.g., a back side) of the device layer 112 vertically opposite the first side, and a through-substrate capacitor structure 140 that extends through the device layer 112 and an STI region 504 in the device layer 112. Opposing ends of the through-substrate capacitor structure 140 extend into a portion of the interconnect layer 114 and into a portion of the interconnect layer 132. The example 910 of the semiconductor die 900 may be formed by processing operations similar to those described in connection with FIGS. 7A-7D and/or 8A-8G.

However, in the example 910, the semiconductor die 900 includes a TSV structure 908 that extends through the device layer 112 and an STI region 504 in the device layer 112, and one or more liners 506 may be included on the sidewalls of the TSV structure 908. Opposing ends of the TSV structure 908 extend into a portion of the interconnect layer 114 and into a portion of the interconnect layer 132. The TSV structure 908 and the through-substrate capacitor structure 140 may both be formed from the back side of the device layer 112 (e.g., during formation of the interconnect layer 114).

In some implementations, the bottom electrode 142 and the top electrode 144 of the through-substrate capacitor structure 140 and the TSV structure 908 are formed of the same material such as copper (Cu). In some implementations, the bottom electrode 142 and the top electrode 144 of the through-substrate capacitor structure 140 are formed of copper (Cu), and the TSV structure 908 are formed of a different material such as tungsten (W).

In some implementations, the TSV structure 908 and the through-substrate capacitor structure 140 may be formed at different times. For example, the process loop for forming the TSV structure 908 may be performed first, followed by the process loop for forming the through-substrate capacitor structure 140. As another example, the process loop for forming the through-substrate capacitor structure 140 may be performed first, followed by the process loop for forming the TSV structure 908.

As shown in FIG. 9E, an example 912 of the semiconductor die 900 is similar to the semiconductor die 104, and includes a device layer 112 (e.g., a semiconductor layer or substrate layer), an interconnect layer 114 on a first side (e.g., a front side) of the device layer 112, an interconnect layer 132 on a second side (e.g., a back side) of the device layer 112 vertically opposite the first side, and a through-substrate capacitor structure 140 that extends through the device layer 112 and into a portion of the interconnect layer 114. The example 912 of the semiconductor die 900 may be formed by similar processing operations described in connection with FIGS. 3A-3H and/or 4A-4D.

However, in the example 912, the semiconductor die 900 includes a TSV structure 908 that extends through the device layer and into a portion of the interconnect layer 114. The through-substrate capacitor structure 140 may be formed from the front side of the device layer 112 (e.g., during formation of the interconnect layer 114), whereas the TSV structure 908 may be formed from the back side of the semiconductor die 900 (e.g., during formation of the interconnect layer 132). Thus, the through-substrate capacitor structure 140 and the TSV structure 908 may have opposing sidewall tapers. For example, the through-substrate capacitor structure 140 may have a sidewall taper such that the width of the through-substrate capacitor structure 140 increases from the interconnect layer 132 to the interconnect layer 114, whereas the TSV structure 908 may have a sidewall taper such that the width of the TSV structure 908 increases from the interconnect layer 114 to the interconnect layer 132.

As shown in FIG. 9F, an example 914 of the semiconductor die 900 is similar to the semiconductor die 502, and includes a device layer 112 (e.g., a semiconductor layer or substrate layer), an interconnect layer 114 on a first side (e.g., a front side) of the device layer 112, an interconnect layer 132 on a second side (e.g., a back side) of the device layer 112 vertically opposite the first side, and a through-substrate capacitor structure 140 that extends through the device layer 112 and an STI region 504 in the device layer 112. Opposing ends of the through-substrate capacitor structure 140 extend into a portion of the interconnect layer 114 and into a portion of the interconnect layer 132. The example 914 of the semiconductor die 900 may be formed by processing operations similar to those described in connection with FIGS. 7A-7D and/or 8A-8G.

However, in the example 914, the semiconductor die 900 includes a TSV structure 908 that extends through the device layer 112 and into a portion of the interconnect layer 132. The through-substrate capacitor structure 140 may be formed from the back side of the device layer 112 (e.g., during formation of the interconnect layer 132), whereas the TSV structure 908 may be formed from the front side of the semiconductor die 900 (e.g., during formation of the interconnect layer 114). Thus, the through-substrate capacitor structure 140 and the TSV structure 908 may have opposing sidewall tapers. For example, the through-substrate capacitor structure 140 may have a sidewall taper such that the width of the through-substrate capacitor structure 140 increases from the interconnect layer 114 to the interconnect layer 132, whereas the TSV structure 908 may have a sidewall taper such that the width of the TSV structure 908 increases from the interconnect layer 132 to the interconnect layer 114.

As shown in FIG. 9G, an example 916 of the semiconductor die 900 is similar to the semiconductor die 104, and includes a device layer 112 (e.g., a semiconductor layer or substrate layer), an interconnect layer 114 on a first side (e.g., a front side) of the device layer 112, and an interconnect layer 132 on a second side (e.g., a back side) of the device layer 112 vertically opposite the first side.

However, in the example 916, the semiconductor die 900 includes a through-substrate capacitor structure 140a (e.g., a back side through-substrate capacitor structure) that extends through the device layer 112 and an STI region 504 in the device layer 112 and a through-substrate capacitor structure 140b (e.g., a front side through-substrate capacitor structure) that extends through the device layer 112 and into a portion of the interconnect layer 114.

The example 906 of the semiconductor die 900 may be formed by similar processing operations described in connection with FIGS. 3A-3H, 4A-4D, 7A-7D, and/or 8A-8G. In some implementations, the through-substrate capacitor structure 140b is formed from the front side of the device layer 112 (e.g., during formation of the interconnect layer 114), and the through-substrate capacitor structure 140a may be formed from the back side of the device layer 112 (e.g., during formation of the interconnect layer 132).

As indicated above, FIGS. 9A-9G are provided as examples. Other examples may differ from what is described with regard to FIG. 9A9G.

FIG. 10 is a diagram of an example semiconductor package 1000 described herein. FIG. 10 illustrates a cross-section view of the semiconductor package 1000. As shown in FIG. 10, the semiconductor package 1000 includes a similar combination and arrangement of layers and/or structures as the semiconductor package 100 illustrated in FIG. 1. However, the semiconductor package 1000 includes a semiconductor die 1002 as opposed to the semiconductor die 104.

As shown in FIG. 10, the semiconductor die 1002 is similar to the semiconductor die 104, and includes a device layer 112 (e.g., a semiconductor layer or substrate layer), an interconnect layer 114 on a first side (e.g., a front side) of the device layer 112, an interconnect layer 132 on a second side (e.g., a back side) of the device layer 112 vertically opposite the first side, and a through-substrate capacitor structure 140 that extends through the device layer 112 and into a portion of the interconnect layer 114.

However, in the semiconductor die 1002, the through-substrate capacitor structure 140 is electrically coupled and/or physically coupled to a top metal layer 1004 in the interconnect layer 114. The top metal layer 1004 may include a layer of top conductive structures that electrically connect the conductive structures 128 (e.g., local interconnect, global interconnects) with the bonding pads 130 of the interconnect layer 114. The top metal layer 1004 may have a greater vertical thickness and/or a greater lateral width than the conductive structures 128 such that the top metal layer 1004 can accommodate greater electrical currents compared to the conductive structures.

Electrically connecting the through-substrate capacitor structure 140 to the top metal layer 1004 may enable the vertical height of the through-substrate capacitor structure 140 to be further increased, which increases the surface area of the bottom electrode 142 and the top electrode 144, which further increases the capacitance of the through-substrate capacitor structure 140.

In some implementations, the semiconductor package 1000 may be formed by processing operations similar to those described in connection with FIGS. 3A-3H and/or 4A-4D. In some implementations, the semiconductor package 1000 may be formed by processing operations similar to those described in connection with FIGS. 7A-7D and/or 8A-8G.

As indicated above, FIG. 10 is provided as an example. Other examples may differ from what is described with regard to FIG. 10.

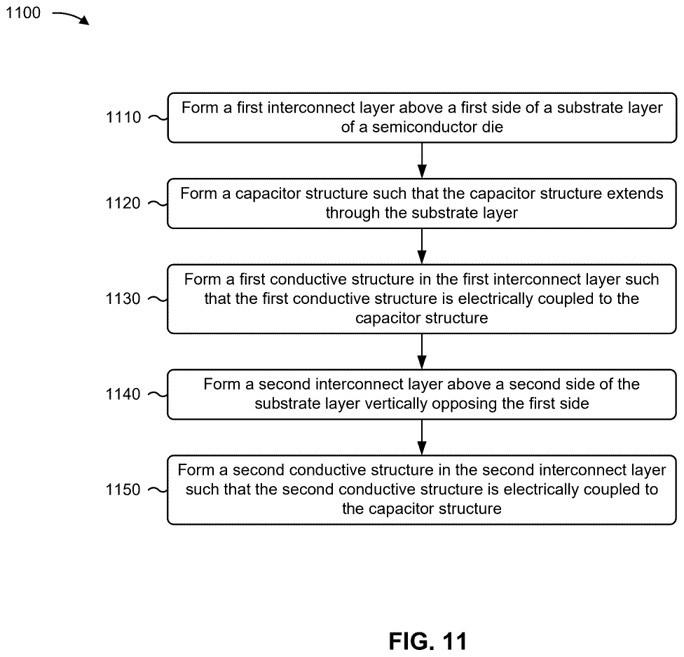

FIG. 11 is a flowchart of an example process 1100 associated with forming a semiconductor device described herein. In some implementations, one or more process blocks of FIG. 11 are performed using one or more semiconductor processing tools, such as a deposition tool, an exposure tool, a developer tool, an etch tool, a planarization tool, an ion implantation tool, an annealing tool, a wafer/die transport tool, and/or another type of semiconductor processing tool.

As shown in FIG. 11, process 1100 may include forming a first interconnect layer above a first side of a substrate layer of a semiconductor die (block 1110). For example, one or more semiconductor processing tools may be used to form a first interconnect layer (e.g., an interconnect layer 114) above a first side (e.g., a front side) of a substrate layer (e.g., a device layer 112) of a semiconductor die (e.g., a semiconductor die 104, a semiconductor die 502, a semiconductor die 900, a semiconductor die 1002), as described herein.

As further shown in FIG. 11, process 1100 may include forming a capacitor structure in the substrate layer (block 1120). For example, one or more semiconductor processing tools may be used to form a capacitor structure (e.g., a through-substrate capacitor structure 140) in the substrate layer, as described herein. In some implementations, the capacitor structure extends into the substrate layer. In some implementations, the capacitor structure is formed such that the capacitor structure extends through the substrate layer. In some implementations, the capacitor structure is formed such that the capacitor structure extends into the substrate layer, and a subsequent wafer grinding operation is performed to remove material from the substrate layer such that the capacitor structure extends through the substrate layer.

As further shown in FIG. 11, process 1100 may include forming a first conductive structure in the first interconnect layer such that the first conductive structure is electrically coupled to the capacitor structure (block 1130). For example, one or more semiconductor processing tools may be used to deposit material of a first conductive structure (e.g., a conductive structure 128, a top metal layer 1004) in the first interconnect layer such that the first conductive structure is electrically coupled to the capacitor structure, as described herein.

As further shown in FIG. 11, process 1100 may include forming a second interconnect layer above a second side of the substrate layer opposing the first side (block 1140). For example, one or more semiconductor processing tools may be used to form a second interconnect layer (e.g., an interconnect layer 132) above a second side (e.g., a back side) of the substrate layer opposing the first side, as described herein. In some implementations, the second side of the substrate layer is vertically opposite the first side of the substrate layer.

As further shown in FIG. 11, process 1100 may include forming a second conductive structure in the second interconnect layer such that the second conductive structure is electrically coupled to the capacitor structure (block 1150). For example, one or more semiconductor processing tools may be used to deposit material of a second conductive structure (e.g., second conductive structure 136) in the second interconnect layer such that the second conductive structure is electrically coupled to the capacitor structure, as described herein.

Process 1100 may include additional implementations, such as any single implementation or any combination of implementations described below and/or in connection with one or more other processes described elsewhere herein.

In a first implementation, forming the capacitor structure includes forming a first portion of the first interconnect layer, etching the first portion of the first interconnect layer and the substrate layer to form a recess (e.g., a recess 302) through the first portion of the first interconnect layer and into the substrate layer, forming the capacitor structure in the recess, and forming a second portion of the first interconnect layer above the first portion after forming the capacitor structure.

In a second implementation, alone or in combination with the first implementation, forming the capacitor structure includes performing a wafer grinding operation to remove material from the second side of the substrate layer, prior to forming the second interconnect layer, such that a bottom of the capacitor structure is exposed through the second side of the substrate layer.

In a third implementation, alone or in combination with one or more of the first and second implementations, forming the capacitor structure includes forming a first portion of the second interconnect layer, etching the first portion of the second interconnect layer, the substrate layer, and the first interconnect layer to form a recess (e.g., a recess 802) through the first portion of the second interconnect layer, through the substrate layer, and into the first interconnect layer, forming the capacitor structure in the recess, and forming a second portion of the second interconnect layer above the first portion after forming the capacitor structure.

In a fourth implementation, alone or in combination with one or more of the first through third implementations, forming the first portion of the second interconnect layer includes forming the first portion of the second interconnect layer after forming the first interconnect layer.

In a fifth implementation, alone or in combination with one or more of the first through fourth implementations, forming the capacitor structure includes forming the capacitor structure after bonding the semiconductor die with another semiconductor die.

Although FIG. 11 shows example blocks of process 1100, in some implementations, process 1100 includes additional blocks, fewer blocks, different blocks, or differently arranged blocks than those depicted in FIG. 11. Additionally, or alternatively, two or more of the blocks of process 1100 may be performed in parallel.

In this way, a semiconductor die in a semiconductor package includes a through-substrate capacitor structure (e.g., a TSV capacitor structure) that extends through the device layer of the semiconductor die. The through-substrate capacitor structure may be electrically connected to a first interconnect layer on a first side (e.g., a front side) of the semiconductor die, and to a second interconnect layer on a second side (e.g., a back side) of the semiconductor die opposing the first side. The through-substrate capacitor structure may also extend into a portion of the first interconnect layer and/or into the second interconnect layer. Forming the through-substrate capacitor structure through the device layer of the semiconductor die enables the through-substrate capacitor structure to be formed to have a high aspect ratio (e.g., a ratio of a height or depth of the through-substrate capacitor structure to a width of the through-substrate capacitor structure), which provides for greater surface area for the bottom electrode layer and the top electrode layer. The greater surface area enables a higher capacitance to be achieved for the through-substrate capacitor structure. Moreover, the first interconnect layer and the second interconnect layer may be electrically connected through the through-substrate capacitor structure.

As described in greater detail above, some implementations described herein provide a semiconductor die. The semiconductor die includes a substrate layer. The semiconductor die includes a first interconnect layer, adjacent to a first side of the substrate layer, that includes one or more first layers of conductive structures. The semiconductor die includes a second interconnect layer, adjacent to a second side of the substrate layer opposing the first side, that includes one or more second layers of conductive structures. The semiconductor die includes a through-substrate capacitor structure extending through the substrate layer from the first side of the substrate layer to the second side of the substrate layer.

As described in greater detail above, some implementations described herein provide a semiconductor package. The semiconductor package includes a first semiconductor die. The first semiconductor die includes a first substrate layer, a first interconnect layer adjacent to a first side of the first substrate layer, a second interconnect layer adjacent to a second side of the first substrate layer opposing the first side, and a through-substrate capacitor structure extending through the first substrate layer and partially into the first interconnect layer. The through-substrate capacitor structure is coupled to a first conductive structure in the first interconnect layer, and the through-substrate capacitor structure is coupled to a second conductive structure in the second interconnect layer. The semiconductor package includes a second semiconductor die. The second semiconductor die includes a second substrate layer a third interconnect layer adjacent to the second substrate layer, where the first interconnect layer of the first semiconductor die is bonded to the third interconnect layer of the second semiconductor die.

As described in greater detail above, some implementations described herein provide a method. The method includes forming a first interconnect layer above a first side of a substrate layer of a semiconductor die. The method includes forming a capacitor structure in the substrate layer. The method includes depositing material of a first conductive structure in the first interconnect layer. The method includes forming a second interconnect layer above a second side of the substrate layer opposing the first side. The method includes depositing material of a second conductive structure in the second interconnect layer. The capacitor structure extends through the substrate layer between the first side and a second side of the substrate layer opposing the first side. The first conductive structure is electrically coupled to the capacitor structure. The second conductive structure is electrically coupled to the capacitor structure.

The terms “approximately” and “substantially” can indicate a value of a given quantity that varies within 5% of the value (e.g., ±1%, ±2%, ±3%, ±4%, ±5% of the value). These values are merely examples and are not intended to be limiting. It is to be understood that the terms “approximately” and “substantially” can refer to a percentage of the values of a given quantity in light of this disclosure.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A semiconductor die, comprising:
a substrate layer;
a first interconnect layer, adjacent to a first side of the substrate layer, comprising one or more first layers of conductive structures;
a second interconnect layer, adjacent to a second side of the substrate layer opposing the first side, comprising one or more second layers of conductive structures; and
a through-substrate capacitor structure extending through the substrate layer from the first side of the substrate layer to the second side of the substrate layer.

2. The semiconductor die of claim 1, wherein the through-substrate capacitor structure partially extends into the first interconnect layer.

3. The semiconductor die of claim 1, wherein the through-substrate capacitor structure comprises:
a bottom electrode;
a top electrode; and
an insulator layer between the bottom electrode and the top electrode,
wherein the top electrode is electrically coupled to a first conductive structure in the one or more first layers of conductive structures, and
wherein the bottom electrode is electrically coupled to a second conductive structure in the one or more second layers of conductive structures.

4. The semiconductor die of claim 3, wherein the bottom electrode comprises a conformal bottom electrode layer; and
wherein the top electrode comprises a top electrode plug.

5. The semiconductor die of claim 1, wherein the through-substrate capacitor structure is electrically connected to an integrated circuit device in the substrate layer through at least one of the first interconnect layer or the second interconnect layer,
wherein the integrated circuit device is adjacent to the through-substrate capacitor structure.

6. The semiconductor die of claim 1, wherein a bottom of the through-substrate capacitor structure is approximately co-planar with a surface of the second side of the substrate layer.

7. The semiconductor die of claim 1, wherein a first width at a top of the through-substrate capacitor structure is greater than a second width at a bottom of the through-substrate capacitor structure; and
wherein the top of the through-substrate capacitor structure is located in the first interconnect layer.

8. A semiconductor package, comprising:
a first semiconductor die, comprising:
a first substrate layer;
a first interconnect layer adjacent to a first side of the first substrate layer;
a second interconnect layer adjacent to a second side of the first substrate layer opposing the first side;
a through-substrate capacitor structure extending through the first substrate layer and partially into the first interconnect layer,
wherein the through-substrate capacitor structure is coupled to a first conductive structure in the first interconnect layer, and
wherein the through-substrate capacitor structure is coupled to a second conductive structure in the second interconnect layer; and
a second semiconductor die, comprising:
a second substrate layer; and
a third interconnect layer adjacent to the second substrate layer,
wherein the first interconnect layer of the first semiconductor die is bonded to the third interconnect layer of the second semiconductor die.

9. The semiconductor package of claim 8, wherein the first conductive structure comprises a top metal layer of the first interconnect layer.

10. The semiconductor package of claim 8, wherein the through-substrate capacitor structure partially extends into the second interconnect layer.

11. The semiconductor package of claim 10, wherein a first width at a top of the through-substrate capacitor structure is greater than a second width at a bottom of the through-substrate capacitor structure; and
wherein the top of the through-substrate capacitor structure is located in the second interconnect layer.

12. The semiconductor package of claim 11, wherein the bottom of the through-substrate capacitor structure is located in the first interconnect layer.

13. The semiconductor package of claim 8, wherein the through-substrate capacitor structure extends through a shallow trench isolation (STI) region in the substrate layer.

14. The semiconductor package of claim 8, further comprising:
one or more liners between the substrate layer and the through-substrate capacitor structure.

15. A method, comprising:
forming a first interconnect layer above a first side of a substrate layer of a semiconductor die;
forming a capacitor structure in the substrate layer,
wherein the capacitor structure extends through the substrate layer between the first side and a second side of the substrate layer opposing the first side;
depositing material of a first conductive structure in the first interconnect layer,
wherein the first conductive structure is electrically coupled to the capacitor structure;
forming a second interconnect layer above the second side of the substrate layer; and
depositing material of a second conductive structure in the second interconnect layer,
wherein the second conductive structure is electrically coupled to the capacitor structure.

16. The method of claim 15, wherein forming the capacitor structure comprises:
forming a first portion of the first interconnect layer;
etching the first portion of the first interconnect layer and the substrate layer to form a recess through the first portion of the first interconnect layer and into the substrate layer;
forming the capacitor structure in the recess; and
forming a second portion of the first interconnect layer above the first portion after forming the capacitor structure.

17. The method of claim 16, wherein forming the capacitor structure comprises:
performing a wafer grinding operation to remove material from the second side of the substrate layer, prior to forming the second interconnect layer, such that a bottom of the capacitor structure is exposed through the second side of the substrate layer.

18. The method of claim 15, wherein forming the capacitor structure comprises:
forming a first portion of the second interconnect layer;
etching the first portion of the second interconnect layer, the substrate layer, and the first interconnect layer to form a recess through the first portion of the second interconnect layer, through the substrate layer, and into the first interconnect layer;
forming the capacitor structure in the recess; and
forming a second portion of the second interconnect layer above the first portion after forming the capacitor structure.

19. The method of claim 18, wherein forming the first portion of the second interconnect layer comprises:
forming the first portion of the second interconnect layer after forming the first interconnect layer.

20. The method of claim 18, wherein forming the capacitor structure comprises:
forming the capacitor structure after bonding the semiconductor die with another semiconductor die.
